(19) United States
(12) Patent Application Publication
(10) Pub. No.: US 2026/0219707 A1
(43) Pub. Date: Jul. 30, 2026

(54) WEARABLE ELECTRONIC DEVICE INCLUDING A PLURALITY OF SWITCH ELEMENTS

(71) Applicant: Samsung Electronics Co., Ltd., Suwon-si (KR)

(72) Inventors: Chungsoon PARK, Suwon-si (KR); Jeongho AHN, Suwon-si (KR); Bareum PARK, Suwon-si (KR); Subin SHIN, Suwon-si (KR); Hansu CHEON, Suwon-si (KR)

(21) Appl. No.: 19/578,205

(22) Filed: Mar. 25, 2026

Related U.S. Application Data
(63) Continuation of application No. PCT/KR2024/014482, filed on Sep. 25, 2024.

(30) Foreign Application Priority Data
Oct. 16, 2023 (KR) 10-2023-0137827
Nov. 17, 2023 (KR) 10-2023-0159737

(51) Int. Cl. G06F 1/16; G04C 10/00; G04G 21/02; H02J 50/10; H05K 7/14

(52) U.S. Cl. CPC G06F 1/163; G04C 10/00; G04G 21/025; H02J 50/10; H05K 7/1427

(57) ABSTRACT

A wearable electronic device is provided. The wearable electronic device includes a housing including a rear plate, a first circuit board disposed inside the housing, a biometric sensor disposed on the rear plate and including a second circuit board, a wireless charger disposed on the rear plate and placed to surround at least part of the biometric sensor, a connector configured to connect the first circuit board and the second circuit board and including a plurality of terminals, a switch circuit configured to connect either the biometric sensor or the wireless charger to the connector, memory, comprising one or more storage media, storing instructions, at least one processor disposed on the first circuit board and electrically connected to the connector, the biometric sensor, and the wireless charger.

### CROSS-REFERENCE TO RELATED APPLICATION(S

This application is a continuation application, claiming priority under 35 U.S.C. § 365(c), of an International application No. PCT/KR2024/014482, filed on September 25, 2024, which is based on and claims the benefit of a Korean patent application number 10-2023-0137827, filed on October 16, 2023, in the Ministry of Intellectual Property (MOIP), and of a Korean patent application number 10-2023-0159737, filed on November 17, 2023, in the Ministry of Intellectual Property (MOIP), the disclosure of each of which is incorporated by reference herein in its entirety

### BACKGROUND

### 1. Field

The disclosure relates to a wearable electronic device including a plurality of switches.

### 2. Description of Related Art

Portable electronic devices such as smartphones may provide a variety of functions, as well as a calling function, based on a variety of applications. To provide various functions through a wearable electronic device, various electronic components need to be integrated within the electronic devices. The wearable electronic devices may include a wireless charging unit and a biometric sensor unit that may acquire a user’s biometric information and provide various health management functions based on the biometric information. However, as the wearable electronic devices become thinner and smaller, there is a growing demand for connectors within these devices to be smaller and have fewer pins. Accordingly, the wearable electronic devices including connectors capable of being reduced in size and pin count are being developed.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide a wearable electronic device including a plurality of switches.

Additional aspects will be set forth in part in the description which follows and, in part, will be apparent from the description, or may be learned by practice of the presented embodiments.

In accordance with an aspect of the disclosure, a wearable electronic device is provided. The wearable electronic device includes a housing including a rear plate, a first circuit board disposed inside the housing, a biometric sensor disposed on the rear plate and including a second circuit board, a wireless charger disposed on the rear plate and placed to surround at least part of the biometric sensor, a connector configured to connect the first circuit board and the second circuit board and including a plurality of terminals, a switch circuit configured to connect either the biometric sensor or the wireless charger to the connector, memory, comprising one or more storage media, storing instructions, and at least one processor disposed on the first circuit board and electrically connected to the connector, the biometric sensor, and the wireless charger, wherein the biometric sensor and the wireless charger share at least one terminal among a plurality of terminals of the connector through the switch circuit, and wherein the switch circuit connects the wireless charger and the connector in response to a wireless charging request of the wearable electronic device, and connects the biometric sensor and the connector in response to a wireless charging non-request of the wearable electronic device.

In accordance with another aspect of the disclosure, method performed by a wearable electronic device including a wireless charger and a biometric sensor disposed on a rear plate is provided. The method includes determining, by the wearable electronic device, whether there is a wireless charging request of the wearable electronic device, based on the wireless charging request of the wearable electronic device, allowing, by the wearable electronic device, a switch circuit disposed between a connector and a wireless charger so as to connect the wireless charger and the connector, which connects a first circuit board disposed on the biometric sensor and a second circuit board included in the biometric sensor, and based on a wireless charging non-request of the wearable electronic device, allowing, by the wearable electronic device, the switch circuit to connect the biometric sensor and the connector, and wherein the biometric sensor unit and the wireless charger share at least one terminal among a plurality of terminals of the connector through the switch circuit.

In accordance with another aspect of the disclosure, one or more non-transitory computer-readable storage media storing one or more computer programs including computer-executable instructions that, when executed by at least one processor of a wearable electronic device individually or collectively, cause the wearable electronic device to perform operations are provided. The operations include determining, by the wearable electronic device, whether there is a wireless charging request of the wearable electronic device including the wireless charger and a biometric sensor disposed on a rear plate, based on the wireless charging request of the wearable electronic device, allowing, by the wearable electronic device, the switch circuit disposed between a connector and a wireless charger so as to connect the wireless charger and the connector, which connects a first circuit board disposed on the biometric sensor and a second circuit board included in the biometric sensor, and based on a wireless charging non-request of the wearable electronic device, allowing, by the wearable electronic device, the switch circuit to connect the biometric sensor and the connector, wherein the biometric sensor and the wireless charger share at least one terminal among a plurality of terminals of the connector through the switch circuit.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an electronic device in a network environment, according to an embodiment of the disclosure;

FIG. 2A is a perspective view of a front surface of an electronic device, according to an embodiment of the disclosure;

FIG. 2B is a perspective view of a rear surface of the electronic device of FIG. 2A according to an embodiment of the disclosure;

FIG. 3 is an exploded perspective view showing an electronic device, according to an embodiment of the disclosure;

FIG. 4 is a schematic block diagram of an electronic device, according to an embodiment of the disclosure;

FIG. 5 is a diagram illustrating an electronic device including a biometric sensor unit, a wireless charging unit, and a magnetic body, according to an embodiment of the disclosure;

FIG. 6A is a diagram illustrating an electronic device including a plurality of switch elements, according to an embodiment of the disclosure;

FIGS. 6B and 6C are diagrams illustrating an operation of an electronic device including a plurality of switch elements illustrated in FIG. 6A according to various embodiments of the disclosure;

FIG. 7A is a diagram illustrating an electronic device including a plurality of switch elements, according to an embodiment of the disclosure;

FIGS. 7B and 7C are diagrams illustrating an operation of an electronic device including a plurality of switch elements illustrated in FIG. 7A according to various embodiments of the disclosure;

FIG. 8 is a flowchart for describing a method of operating an electronic device including a plurality of switch elements, according to an embodiment of the disclosure;

FIG. 9 is a diagram illustrating an electronic device including a plurality of switch elements, according to an embodiment of the disclosure;

FIGS. 10A and 10B are diagrams for describing an operation of an electronic device including a plurality of switch elements, according to various embodiments of the disclosure;

FIG. 11 is a flowchart for describing a method of operating an electronic device including a plurality of switch elements, according to an embodiment of the disclosure; and

FIG. 12 is a diagram illustrating an electronic device including a plurality of switch elements, according to an embodiment of the disclosure.

Throughout the drawings, like reference numerals will be understood to refer to like parts, components, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth^{®} chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

Hereinafter, various embodiments of the disclosure may be described with reference to accompanying drawings.

An embodiment of the disclosure described below provides a wearable electronic device capable of securing the width of a wiring connected to a connector by allowing switch circuits 610, 710, 910, and 1210 to connect the wireless charging unit 520 and the connector 510 based on a wireless charging request of an electronic device, and allowing the switch circuits 610, 710, 910, and 1210 to connect the biometric sensor unit 540 and the connector 510 in response to a wireless charging non-request of the electronic device.

Moreover, an embodiment of the disclosure provides a wearable electronic device capable of securing the width of the wiring connected to the connector, because the switch circuits 610, 710, 910, and 1210 connects the wireless charging unit 520 and the connector 510 in response to the wireless charging request of the electronic device, and connects the biometric sensor unit 540 and the connector 510 in response to the wireless charging non-request of the electronic device.

Other desired objectives according to various embodiments of the disclosure will be mentioned as needed during the description of each embodiment.

The wearable electronic device according to an embodiment may support reducing the number of connection terminals and the size of the connector.

The wearable electronic device according to an embodiment may efficiently utilize the width of the wiring connected to a connection terminal due to the reduction in the number of connection terminals of the connector.

According to an embodiment, the wearable electronic device may add a connection terminal for a new function by reducing the number of connection terminals of the connector.

According to an embodiment, the wearable electronic device may be used as a shared wiring in which at least one of a plurality of connection terminals of the connector is selectively connected to a charging terminal of the wireless charging unit and a power terminal (a ground terminal) of the biometric sensor unit.

Various purposes and effects that the wearable electronic device according to various embodiments provide will be mentioned for each embodiment of the detailed description.

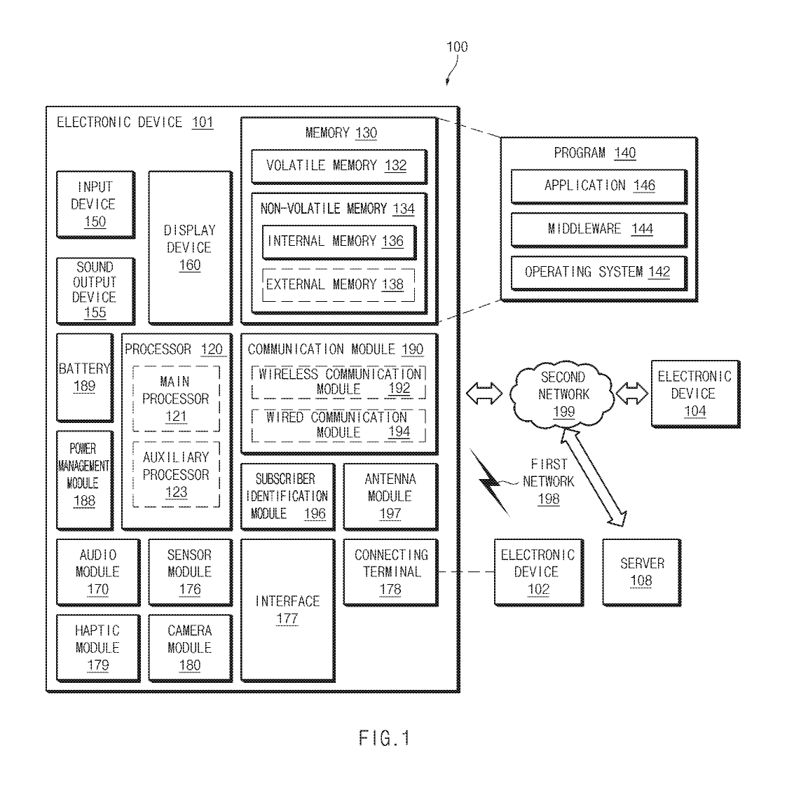

FIG. 1 is a block diagram of an electronic device in a network environment, according to an embodiment of the disclosure.

Referring to FIG. 1, the electronic device 101 in the environment information 100 may communicate with an electronic device 102 over a first network 198 (e.g., a short range wireless communication network) or may communicate with at least one of an electronic device 104 or a server 108 over a second network 199 (e.g., a long distance wireless communication network). According to an embodiment, the electronic device 101 may communicate with the electronic device 104 through the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module 196, or an antenna module 197. In any embodiment, the electronic device 101 may not include at least one (e.g., the connecting terminal 178) of the above-described components or may further include one or more other components. In some embodiments, some (e.g., the sensor module 176, the camera module 180, or the antenna module 197) of these components may be integrated into a single component (e.g., the display module 160).

For example, the processor 120 may execute software (e.g., a program 140) to control at least another component (e.g., hardware or software component) of the electronic device 101 connected to the processor 120, and may process and calculate various types of data. According to an embodiment, as at least part of data processing or calculation, the processor 120 may store instructions or data received from other components (e.g., the sensor module 176 or the communication module 190) into volatile memory 132, may process instructions or data stored in the volatile memory 132, and may store the result data in nonvolatile memory 134. According to an embodiment, the processor 120 may include a main processor 121 (e.g., a central processing unit or an application processor) and an auxiliary processor 123 (e.g., a graphic processing unit, a neural processing unit (NPU), an image signal processor, a sensor hub processor, or a communication processor) capable of operating independently or together with the main processor. For example, when the electronic device 101 includes the main processor 121 and the auxiliary processor 123, the auxiliary processor 123 may be configured to use less power than the main processor 121 or to be specialized for a specified function. The auxiliary processor 123 may be implemented separately from the main processor 121 or as part of the main processor 121.

For example, the auxiliary processor 123 may control at least part of the functions or states associated with at least one (e.g., the display module 160, the sensor module 176, or the communication module 190) of the components of the electronic device 101, instead of the main processor 121 while the main processor 121 is in an inactive (e.g., sleep) state or together with the main processor 121 while the main processor 121 is in an active (e.g., the execution of an application) state. According to an embodiment, the auxiliary processor 123 (e.g., an image signal processor or a communication processor) may be implemented as a part of operatively associated other components (e.g., the camera module 180 or the communication module 190). According to an embodiment, the auxiliary processor 123 (e.g., a neural network processing unit) may include a hardware structure specialized to process an artificial intelligence model. The artificial intelligence model may be generated through machine learning. For example, the learning may be performed in the electronic device 101, in which an artificial intelligence model is performed, or may be performed through a separate server (e.g., the server 108). For example, the learning algorithm may include supervised learning, unsupervised learning, semi-supervised learning, or reinforcement learning, but is not limited to the above example. The artificial intelligence model may include a plurality of artificial neural network layers. The artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination of two or more of the networks, but may not be limited to the above-described example. In addition to a hardware structure, additionally or alternatively, the artificial intelligence model may include a software structure.

The memory 130 may store various pieces of data used by at least one component (e.g., the processor 120 or the sensor module 176) of the electronic device 101. For example, data may include software (e.g., the program 140) and input data or output data for instructions associated with the software. The memory 130 may include the volatile memory 132 or the nonvolatile memory 134. The nonvolatile memory 134 may include internal memory 136 and external memory 138.

The program 140 may be stored in the memory 130 as software, and may include, for example, an operating system 142, a middleware 144, or an application 146.

The input module 150 may receive instructions or data to be used for the component (e.g., the processor 120) of electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output a sound signal to the outside of the electronic device 101. The sound output module 155 may include, for example, a speaker or a receiver. The speaker may be used for a general purpose, such as multimedia play or recording play. The receiver may be used to receive an incoming call. According to an embodiment, the receiver may be implemented separately from the speaker or may be implemented as a part of the speaker.

The display module 160 may visually provide information to the outside (e.g., the user) of the electronic device 101. The display module 160 may include, for example, a display, a hologram device, or a control circuit for controlling a projector and a corresponding device. According to an embodiment, the display module 160 may include a touch sensor configured to sense a touch, or a pressure sensor configured to measure the strength of force generated by the touch.

The audio module 170 may convert sound to an electrical signal, or reversely, may convert an electrical signal to sound. According to an embodiment, the audio module 170 may obtain sound through the input module 150, or may output sound through the sound output module 155, or through an external electronic device (e.g., the electronic device 102) (e.g., a speaker or a headphone) directly or wirelessly connected with the electronic device 101.

The sensor module 176 may sense an operation state (e.g., power or a temperature) of the electronic device 101 or an external environment state (e.g., a user state), and may generate an electrical signal or a data value corresponding the sensed state. According to an embodiment, the sensor module 176 may include, for example, a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, or an illumination sensor.

The interface 177 may support one or more specified protocols that may be used to directly and wirelessly connect the electronic device 101 with an external electronic device (e.g., the electronic device 102). According to an embodiment, the interface 177 may include, for example, an high-definition multimedia interface (HDMI), a universal serial bus (USB) interface, a secure digital (SD) card interface, or an audio interface.

The connecting terminal 178 may include a connector that may allow the electronic device 101 to be physically connected with an external electronic device (e.g., the electronic device 102). According to an embodiment, the connecting terminal 178 may include, for example, a HDMI connector, an USB connector, an SD card connector, or an audio connector (e.g., a headphone connector).

The haptic module 179 may convert an electrical signal to a mechanical stimulation (e.g., vibration or movement) or an electrical stimulation which the user may perceive through the sense of touch or the sense of movement. According to an embodiment, the haptic module 179 may include, for example, a motor, a piezoelectric sensor, or an electrical stimulation device.

The camera module 180 may shoot a still image or a video image. According to an embodiment, the camera module 180 may include one or more lenses, image sensors, image signal processors, or flashes (or electrical flashes).

The power management module 188 may manage the power which is supplied to the electronic device 101. According to an embodiment, the power management module 188 may be implemented, for example, as at least part of a power management integrated circuit (PMIC).

The battery 189 may power at least one component of the electronic device 101. According to an embodiment, the battery 189 may include, for example, a primary cell not rechargeable, a secondary cell rechargeable, or a fuel cell.

The communication module 190 may establish a direct (or wired) communication channel or a wireless communication channel between the electronic device 101 and an external electronic device (e.g., the electronic device 102, the electronic device 104, or the server 108) and may perform communication through the established communication channel. The communication module 190 may include one or more communication processors which are operated independently of the processor 120 (e.g., an application processor) and support direct (or wired) communication or wireless communication. According to an embodiment, the communication module 190 may include a wireless communication module 192 (e.g., a cellular communication module, a short range wireless communication module, or a global navigation satellite system (GNSS) communication module) or a wired communication module 194 (e.g., a local area network (LAN) communication module or a power line communication module). The corresponding communication module among these communication modules may communicate with an external electronic device 104 through a first network 198 (e.g., a short-range communication network such as Bluetooth, wireless fidelity (Wi-Fi) direct or infrared data association (IrDA)) or a second network 199 (e.g., long-range wireless communication network such as a legacy cellular network, fifth generation (5G) networks, next-generation communication networks, Internet, or computer networks (e.g., LAN or wide area network (WAN))). The above-described kinds of communication modules may be integrated in one component (e.g., a single chip) or may be implemented with a plurality of components (e.g., a plurality of chips) which are independent of each other. The wireless communication module 192 may identify or authenticate the electronic device 101 within a communication network, such as the first network 198 or the second network 199, by using subscriber information (e.g., international mobile subscriber identity (IMSI)) stored in the subscriber identification module 196.

The wireless communication module 192 may support a 5G network and a next-generation communication technology after a fourth generation (4G) network, for example, a new radio (NR) access technology. The NR access technology may support enhanced mobile broadband (eMBB), massive machine type communications (mMTC), or ultra-reliable and low-latency communications (URLLC). For example, the wireless communication module 192 may support a high frequency band (e.g., millimeter wave (mmWave) band) to achieve a high data transfer rate. The wireless communication module 192 may support various technologies for securing performance in a high frequency band, for example, technologies such as beamforming, massive multiple-input and multiple-output (massive MIMO), full dimensional MIMO (FD-MIMO), an array antenna, analog beam-forming, and a large scale antenna. The wireless communication module 192 may support various requirements regulated in the electronic device 101, an external electronic device (e.g., the electronic device 104) or a network system (e.g., the second network 199). According to an embodiment, the wireless communication module 192 may support peak data rate (e.g., 20 Gbps or more) for eMBB implementation, loss coverage (e.g., 164 dB or less) for mMTC implementation, or U-plane latency (e.g., downlink (DL) of 0.5 ms or less and uplink (UL) of 0.5 ms or less, or round trip of 1 ms or less) for URLLC implementation.

The antenna module 197 may transmit a signal or a power to the outside (e.g., an external electronic device) or may receive a signal or a power from the outside. According to an embodiment, the antenna module 197 may include an antenna including a radiator formed of a conductor or a conductive pattern formed on a substrate (e.g., printed circuit board (PCB)). According to an embodiment, the antenna module 197 may include a plurality of antennas (e.g., an array antenna). In this case, at least one antenna suitable for a communication scheme used in a communication network such as the first network 198 or the second network 199 may be selected, for example, by the communication module 190 from the plurality of antennas. The signal or power may be exchanged between the communication module 190 and an external electronic device through the selected at least one antenna or may be received from the external electronic device through the selected at least one antenna and the communication module 190. According to an embodiment, other parts (e.g., radio frequency integrated circuit (RFIC)) may be additionally formed as a part of the antenna module 197 in addition to the radiator.

According to an embodiment, the antenna module 197 may form an mmWave antenna module. According to an embodiment, the mmWave antenna module may include a printed circuit board (PCB), a radio frequency integrated circuit (RFIC), and a plurality of antennas (e.g., an array antenna). The RFIC may be disposed on or adjacent to a first surface (e.g., a bottom surface) of the PCB and may support a specified high frequency band (e.g., mmWave band). The plurality of antennas may be disposed on or adjacent to a second surface (e.g., a top surface or a side surface) of the PCB and may transmit or receive a signal in the specified high frequency band.

At least some of the components may be connected to each other through a communication scheme (e.g., a bus, a general purpose input and output (GPIO), a serial peripheral interface (SPI), or a mobile industry processor interface (MIPI)) between peripheral devices and may exchange signals (e.g., commands or data) with each other.

According to an embodiment, the command or data may be transmitted or received between the electronic device 101 and the external electronic device 104 through the server 108 connected to the second network 199. Each of the external electronic device 102 or 104 may be a device of which the type is the same as or different from that of the electronic device 101. According to an embodiment, all or a part of operations to be executed by the electronic device 101 may be executed in one or more external electronic devices among the external electronic devices 102, 104, or the server 108. For example, when the electronic device 101 needs to perform any function or service automatically or in response to a request from the user or any other device, the electronic device 101 may additionally request one or more external electronic devices to perform at least part of the function or service, instead of internally executing the function or service. The one or more external electronic devices which receive the request may execute at least a part of the function or service thus requested or an additional function or service associated with the request, and may provide a result of the execution to the electronic device 101. The electronic device 101 may process the result as it is or additionally, and may provide a result of the processing as at least a part of the response to the request. To this end, for example, cloud computing, distributed computing, mobile edge computing (MEC), or client-server computing may be used. For example, the electronic device 101 may provide an ultra-low latency service by using distributed computing or mobile edge computing. In another embodiment, the external electronic device 104 may include an Internet of Things (IoT) device. The server 108 may be an intelligent server using machine learning and/or a neural network. According to an embodiment, the external electronic device 104 or the server 108 may be included in the second network 199. The electronic device 101 may be applied to an intelligent service (e.g., a smart home, a smart city, a smart car, or a healthcare) based on 5G communication technology and IoT-related technology.

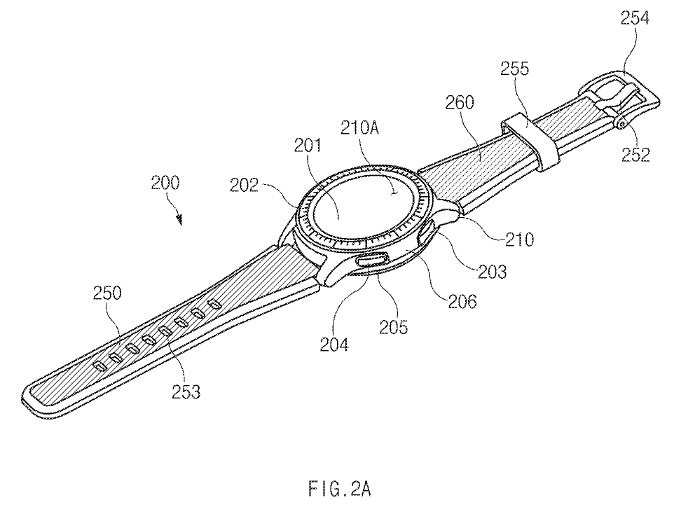

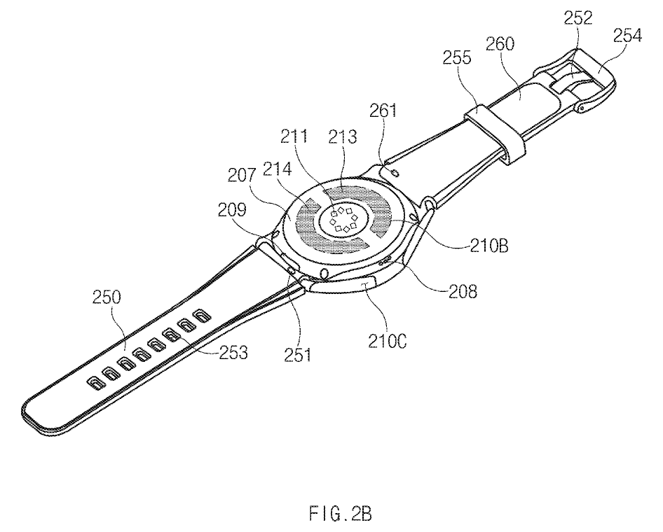

FIG. 2A is a perspective view of a front surface of an electronic device, according to an embodiment of the disclosure.

FIG. 2B is a perspective view of a rear surface of the electronic device of FIG. 2A according to an embodiment of the disclosure.

Referring to FIGS. 2A and 2B, an electronic device 200 (e.g., the electronic device 101 of FIG. 1) according to an embodiment may include the housing 210 including a first surface (or a front surface) 210A, a second surface (or a rear surface) 210B, and a side surface 210C surrounding a space between the first surface 210A and the second surface 210B, and binding members 250 and 260 connected to at least part of the housing 210 and configured to detachably bind the electronic device 200 to a body part (e.g., a wrist or an ankle) of a user. In another embodiment (not illustrated), the housing may refer to a structure that forms a part of the first surface 210A, the second surface 210B, and the side surfaces 210C of FIG. 2A. According to an embodiment, the first surface 210A may be formed by a front plate 201 (e.g., a glass plate including various coating layers, or a polymer plate), at least a portion of which is substantially transparent. The second surface 210B may be formed by a rear plate 207 that is substantially opaque. For example, the rear plate 207 may be formed of a coated or colored glass, a ceramic, a polymer, a metal (e.g., aluminum, stainless steel (STS), or magnesium), or the combination of at least two of the materials. The side surface 210C may be coupled to the front plate 201 and the rear plate 207 and may be formed by a side bezel structure (or a “side member”) 206 including a metal and/or a polymer. In an embodiment, the rear plate 207 and the side bezel structure 206 may be integrally formed and may include the same material (e.g., a metal material such as aluminum). The binding members 250 and 260 may be formed in various materials and shapes. They may be formed such that the integral type and a plurality of unit links are capable of being moved with each other by woven fabric, leather, rubber, urethane, metal, ceramic, or the combination of at least two of the materials.

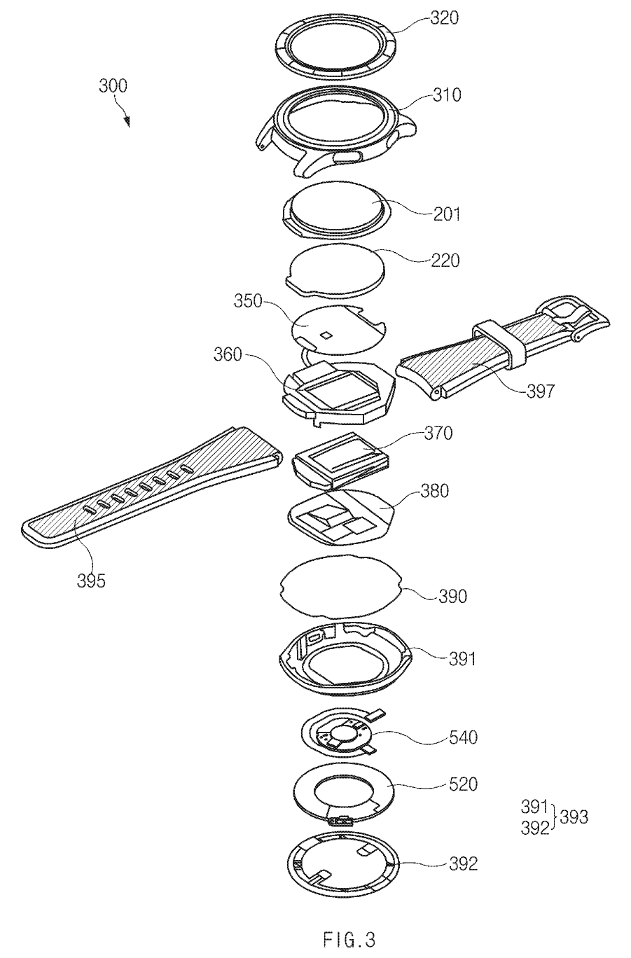

According to an embodiment, the electronic device 200 may include at least one or more of a display 220 (see FIG. 3), audio modules 205 and 208, a sensor module 211, key input devices 202, 203, and 204, and a connector hole 209. In any embodiment, the electronic device 200 may not include at least one (e.g., the key input device 202, 203, or 204, the connector hole 209, or the sensor module 211) of the components or may further include any other component.

For example, the display 220 may be exposed through a substantial portion of the front plate 201. The shape of the display 220 may be a shape corresponding to the shape of the front plate 201, and may have various shapes such as a circle, an ellipse, or a polygon. The display 220 may be coupled to a touch sensing circuit, a pressure sensor capable of measuring the intensity (or pressure) of a touch, and/or a fingerprint sensor or may be disposed adjacent thereto.

The audio modules 205 and 208 may include the microphone hole 205 and the speaker hole 208. A microphone for obtaining external sound may be disposed within the microphone hole 205; in any embodiment, a plurality of microphones may be disposed to detect a direction of sound. The speaker hole 208 may be used as an external speaker and a call receiver. In any embodiment, the speaker hole 208 and the microphone hole 205 may be implemented with one hole, or a speaker (e.g., a piezo speaker) may be included without the speaker hole 208.

The sensor module 211 may generate an electrical signal or a data value that corresponds to an internal operation state of the electronic device 200 or an external environment state. The sensor module 211 may include, for example, the biometric sensor module 211 (e.g., a heart rate monitor (HRM) sensor) positioned on the second surface 210B of the housing 210. The electronic device 200 may further include a sensor module not illustrated, for example, at least one of a gesture sensor, a gyro sensor, a barometric pressure sensor, a magnetic sensor, an acceleration sensor, a grip sensor, a color sensor, an infrared (IR) sensor, a biometric sensor, a temperature sensor, a humidity sensor, or an illumination sensor.

The sensor module 211 may include electrode regions 213 and 214 forming a portion of the surface of the electronic device 200 and a biometric signal detection circuit (not shown) electrically connected to the electrode regions 213 and 214. For example, the electrode regions 213 and 214 may include the first electrode region 213 and the second electrode region 214, which are placed on the second surface 210B of the housing 210. The sensor module 211 may be configured such that the electrode regions 213 and 214 acquire electrical signals from a portion of the user’s body, and the biometric signal detection circuit detects biometric information of the user based on the electrical signals.

The key input devices 202, 203, and 204 may include the wheel key 202 positioned on the first surface 210A of the housing 210 and rotatable in at least one direction and/or side key buttons 203 and 204 positioned on the side surface 210C of the housing 210. The wheel key may have a shape corresponding to the shape of the front plate 201 (i.e., front surface plate). In another embodiment, the electronic device 200 may not include all or a part of the key input devices 202, 203, and 204 mentioned above, and the key input devices 202, 203, and 204 not included may be implemented on the display 220 in a form such as a soft key. The connector hole 209 may include another connector hole (not illustrated) capable of accommodating a connector (e.g., a USB connector) for transmitting/receiving power and/or data to/from an external electronic device and accommodating a connector for transmitting/receiving an audio signal to/from the external electronic device. For example, the electronic device 200 may further include a connector cover (not illustrated) that covers at least part of the connector hole 209 and blocks the inflow of external foreign substances to the connector hole. In another embodiment, the electronic device 200 may not include some or all of the connector hole 209 and the connector cover.

The binding members 250 and 260 may be detachably bound to at least a partial area of the housing 210, using locking members 251 and 261. The binding members 250 and 260 may include one or more of a fixing member 252, a fixing member fastening hole 253, a band guide member 254, and a band fixing ring 255.

The fixing member 252 may be configured to fix the housing 210 and the binding members 250 and 260 to the user’s body part (e.g., a wrist or an ankle). The fixing member fastening hole 253 may fix the housing 210 and the binding members 250 and 260 to the user’s body part in compliance with the fixing member 252. The band guide member 254 may be configured to limit the motion range of the fixing member 252 when the fixing member 252 is fastened with the fixing member fastening hole 253, and thus may allow the binding members 250 and 260 to be bound to the user’s body part while being in close contact. In a state where the fixing member 252 is fastened to the fixing member fastening hole 253, the band fixing ring 255 may limit the motion range of the binding members 250 and 260. In another embodiment, the binding members 250 and 260 may not include one or more of the fixing member 252, the fixing member fastening hole 253, the band guide member 254, and the band fixing ring 255. For example, the binding members 250 and 260 may be combined with each other to form a ring shape, and thus may not include the fixing member 252, the fixing member fastening hole 253, the band guide member 254, and the band fixing ring 255.

FIG. 3 is an exploded perspective view showing an electronic device, according to an embodiment of the disclosure.

Referring to FIG. 3, an electronic device 300 (e.g., the electronic device 101 of FIG. 1 or the electronic device 200 of FIG. 2A) may include a side surface bezel structure 310 (e.g., the side bezel structure 206 of FIG. 2A (i.e., the side surface bezel structure)) (alternatively, a side surface frame or a side surface member), a wheel key 320 (e.g., the wheel key 202 of FIG. 2A), the front plate 201 (i.e., front surface plate), the display 220, an antenna 350, a support member 360 (e.g., a bracket), the battery 370, the printed circuit board 380 (alternatively, a first circuit board or a main circuit board), a sealing member 390, the rear plate 393 (e.g., the rear plate 207 of FIG. 2B), and binding members 395 and 397 (e.g., the binding members 250 and 260 of FIGS. 2A and 2B). At least one of the components of the electronic device 300 may be identical or similar to at least one of the components of the electronic device 200 of FIGS. 1 or 2, and thus, additional description will be omitted to avoid redundancy. The support member 360 may be disposed within the electronic device 300, and may be connected with the side surface bezel structure 310 or may be integrally formed with the side surface bezel structure 310. For example, the support member 360 may be formed of a metal material and/or a nonmetal material (e.g., polymer). The display 220 may be coupled to one surface of the support member 360, and the printed circuit board 380 may be coupled to the other surface of the support member 360. A processor, memory, and/or an interface may be mounted on the printed circuit board 380. The processor may include, for example, one or more of a central processing unit, an application processor, a graphic processing unit, a sensor processor, or a communication processor.

The memory may include, for example, volatile memory or nonvolatile memory. The interface may include, for example, a high definition multimedia interface (HDMI), a universal serial bus (USB) interface, a secure digital (SD) card interface, and/or an audio interface. The interface may electrically or physically connect, for example, the electronic device 300 with an external electronic device and may include a USB connector, an SD card/multimedia card (MMC) connector, or an audio connector.

The battery 370 that is a device for supplying power to at least one component of the electronic device 300 may include, for example, a primary cell incapable of being recharged, a secondary cell rechargeable, or a fuel cell. At least part of the battery 370 may be disposed on substantially the same plane as the printed circuit board (PCB) 380, for example. The battery 370 may be integrally disposed within the electronic device 200 or may be disposed to be removable from the electronic device 200.

The sealing member 390 may be located between the side surface bezel structure 310 and the rear plate 393. The sealing member 390 may be configured to block moisture and foreign substances from entering a space, which is enclosed by the side surface bezel structure 310 and the rear plate 393, from the outside.

The rear plate 393 may include the first cover plate 391 coupled to the side surface bezel structure 310, and the second cover plate 392 coupled to the first cover plate 391.

At least part of the second cover plate 392 may be formed transparently such that light passes for the operation of the biometric sensor unit 540 (or the biometric sensor). For example, the second cover plate 392 may include a transparent area formed at locations corresponding to a light emitting unit and a light receiving unit of the biometric sensor unit 540. Light generated from the light emitting unit of the biometric sensor unit 540 may pass through the transparent area of the second cover plate 392 to reach an external object (e.g., the user’s wrist), and light reflected from the external object may pass through the transparent area of the second cover plate 392 to reach the light receiving unit.

The rear plate 393 may support the wireless charging unit 520 (or the wireless charger) and the biometric sensor unit 540. For example, the wireless charging unit 520 and the biometric sensor unit 540 may be placed in the space between the first cover plate 391 and the second cover plate 392. The wireless charging unit 520 generates an induced current in response to an external electromagnetic field, and may supply power of the electronic device 300 or charge the battery 370, by using the generated induced current. For example, the coil antenna included in the wireless charging unit 520 may perform short-range communication with an external device or may wirelessly transmit/receive power necessary for charging, and may transmit a short-range communication signal or a magnetic-based signal including payment data. In another embodiment, an antenna structure may be formed by a part of the side bezel structure 310 and/or the rear plate 393, or by a combination thereof.

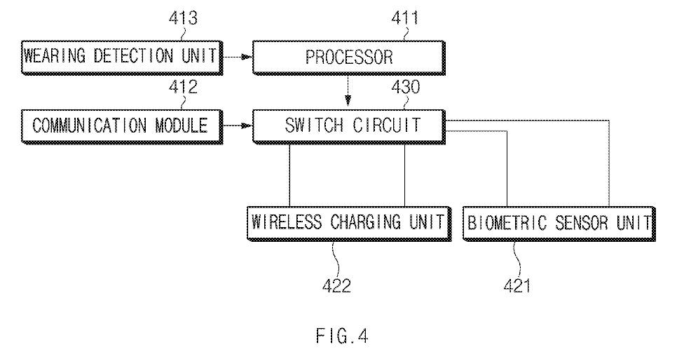

FIG. 4 is a schematic block diagram of an electronic device, according to an embodiment of the disclosure.

Referring to FIG. 4, an electronic device according to an embodiment may include at least one of the processor 411 (e.g., the processor 120 of FIG. 1), a communication module 412 (e.g., the communication module 190 of FIG. 1), a wearing detection unit 413, a switch circuit 430, a wireless charging unit 422 (e.g., the wireless charging unit 520 of FIG. 3), and a biometric sensor unit 421 (e.g., the biometric sensor unit 540 of FIG. 3). All or part of the functions of each component of the electronic device of FIG. 4 may be included in at least one element of FIG. 1.

The communication module 412 may communicate with a server (e.g., the server 108 of FIG. 1) or another electronic device (e.g., the electronic device 102 or 103 of FIG. 1) in various ways. For example, the communication module 412 may perform wireless communication with an external electronic device (e.g., a wireless charging circuit). For example, the communication module 412 may communicate with an external electronic device by using a plurality of coil antennas. For example, the communication module 412 may communicate with an external electronic device by using at least one of Bluetooth, Bluetooth low energy (BLE), Wi-Fi, and near-field communication (NFC).

The communication module 412 may transmit packet information related to wireless charging power control to an external electronic device. The external electronic device may determine the location of the electronic device based on the received packet information and may wirelessly supply power to the electronic device. For example, the packet information may include at least one of a control error packet (CEP) signal, which includes notification information about the power (or the amount of power) required by the electronic device for charging, and a received power packet (RPP) signal, which includes information about power (or the amount of power) received by the electronic device.

According to an embodiment, when detecting the packet information about wireless charging power control transmitted to the external electronic device, the communication module 412 (or the wireless charging unit 422) may generate a charging detection signal and may allow a switching unit to operate the electronic device in a wireless charging mode.

The wearing detection unit 413 may detect whether the electronic device is worn on a user’s body and may deliver the wearing detection result to the processor 411. For example, the wearing detection unit 413 may include a proximity sensor, a grip sensor, an acceleration sensor, a gyro sensor, a 6-axis sensor, and/or a 9-axis sensor.

A plurality of switch elements included in the switch circuit 430 may operate (or switch) based on a charge detection signal received through a GPIO of the processor 411, a charge detection signal from the communication module 412 (or the wireless charging unit 422), or a wearing detection signal received through a GPIO of the processor 411.

According to an embodiment, the switch circuit 430 may electrically connect a first circuit board (e.g., the first circuit board 380 of FIG. 3), on which the processor 411 is disposed, to one of the wireless charging unit 422 and the biometric sensor unit 421 based on the charge detection signal and/or the wearing detection signal.

According to an embodiment, on the basis of a wearing detection signal, the switch circuit 430 may electrically connect the biometric sensor unit 421 to a first circuit board (e.g., the first circuit board 380 of FIG. 3), on which the processor 411 is disposed, and may disconnect the electrical connection between the first circuit board and the wireless charging unit 422. On the basis of a charge detection signal, the switch circuit 430 may electrically connect the first circuit board and the wireless charging unit 422 and may disconnect the electrical connection between the first circuit board and the biometric sensor unit 421.

According to an embodiment, on the basis of a charge detection signal of first logic (e.g., high logic or logic corresponding to 1), the switch circuit 430 may electrically connect the first circuit board and the wireless charging unit 422 and may disconnect the electrical connection between the first circuit board and the biometric sensor unit 421. On the basis of the charge detection signal of the second logic (e.g., low logic or logic corresponding to 0), the switch circuit 430 may electrically connect the first circuit board and the biometric sensor unit 421, and may disconnect the electrical connection between the first circuit board and the wireless charging unit 422.

According to an embodiment, when it is determined that the electronic device is in contact with (or connected to) an external electronic device (e.g., a wireless charging device), the processor 411 may be configured such that the electronic device operates in a wireless charging mode. When it is determined that the electronic device is not in contact with (or connected to) the external electronic device (e.g., a wireless charging device), the processor 411 may be configured such that the electronic device operates in a biometric sensing mode. When the electronic device is worn on the user’s body, the processor 411 may operate in the biometric sensing mode without delay.

According to an embodiment, when it is determined that the electronic device is worn on the user’s body, the processor 411 may be configured such that the electronic device operates in a biometric sensing mode. When it is determined that the electronic device is not worn on the user’s body and is not in contact with (or connected to) the external electronic device (e.g., a wireless charging device), the processor 411 may be configured such that the electronic device operates in a biometric sensing mode.

According to an embodiment, when a charging voltage applied to a battery (e.g., the battery 370 in FIG. 3) of the electronic device from an external electronic device is detected for a specified period of time, the processor 411 may generate a charge detection signal and may control the switching circuit 430 such that the electronic device operates in a wireless charging mode.

According to an embodiment, when receiving information about whether the electronic device is being worn, from the wearing detection unit 413, the processor 411 may generate a wearing detection signal and may control the switching unit such that the electronic device operates in a biometric sensing mode.

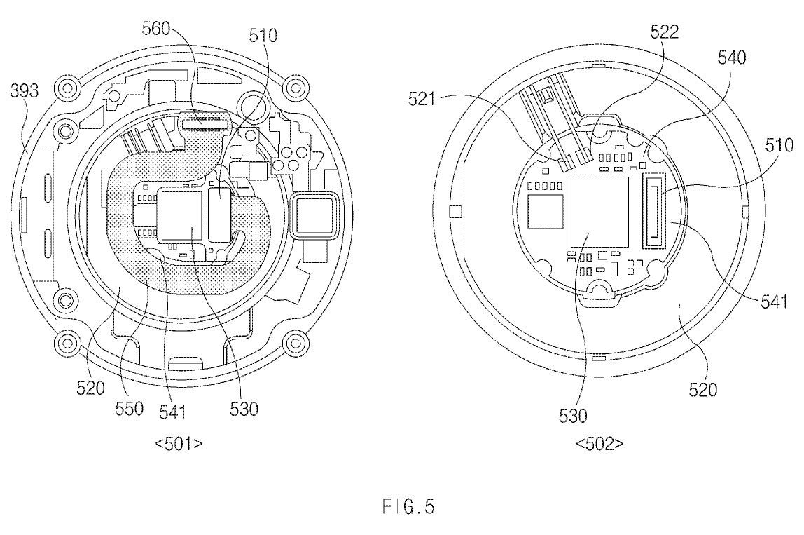

FIG. 5 is a diagram illustrating an electronic device including a biometric sensor unit, a wireless charging unit, and a magnetic body, according to an embodiment of the disclosure. In FIG. 5, drawing <501> illustrates a state where a biometric sensor unit, a wireless charging unit, and the rear plate 393 (e.g., the first rear plate 391 of FIG. 3) are combined with each other, and drawing <502> illustrates an electronic device including a biometric sensor unit and a wireless charging unit with the rear plate omitted.

Referring to FIG. 5, an electronic device according to an embodiment may include the rear plate 393, the biometric sensor unit 540, the wireless charging unit 520, and a magnetic body 530.

The rear plate 393 (e.g., the first rear plate 391 of FIG. 3) may include an outer surface facing the rear surface of the electronic device (e.g., the surface 210B of FIG. 2B) and an inner surface facing the front surface of the electronic device (e.g., the first surface 210A of FIG. 2A (i.e., front surface)). According to an embodiment, when the electronic device is to be worn on a user’s wrist, the outer surface of the rear plate 393 may face the user’s wrist.

Various components, such as the biometric sensor unit 540, the wireless charging unit 520 (e.g., the wireless charging antenna 350 included in the electronic component of FIG. 3), and the magnetic body 530, may be placed adjacent to the rear plate 393. The biometric sensor unit 540 may obtain biometric information of a user through a substantially transparent area of the rear plate 393 (e.g., the second cover plate 392).

The biometric sensor unit 540 may measure a biometric signal of the user of the electronic device. For example, the biometric sensor unit 540 may include at least one of a heartbeat rate monitor (HRM) sensor capable of measuring a heart rate of the user, an electrocardiogram (ECG) sensor capable of measuring an electrocardiogram of the user, a photoplethysmography (PPG) sensor capable of measuring the user’s photoplethysmography, a bioelectric impedance analysis (BIA) sensor capable of measuring a body fat percentage of the user, and/or a galvanic skin response (GSR) sensor capable of measuring a skin resistance of the user.

The biometric sensor unit 540 may include the second circuit board 541 (alternatively, an auxiliary circuit board or a flexible printed circuit board). The second circuit board 541 may be electrically connected to the first circuit board (e.g., the printed circuit board 380 of FIG. 3) via a connection circuit member. The connection circuit member may be formed of a flexible material such that bending is capable of being permitted. The connection circuit member may be connected to the second circuit board 541 through the connector 510 (or a connection terminal) formed at one end, and may be connected to the first circuit board through a connector 560 formed at the other end via the wireless charging unit 520 surrounding the second circuit board 541.

The second circuit board 541 may include a first surface facing the first cover plate 391 and a second surface facing the second cover plate (e.g., the second cover plate 392 of FIG. 3). The connectors 510 and 560 and various electrical elements may be placed on the first surface of the second circuit board 541, and a light emitting unit and a light receiving unit may be placed on the second surface of the second circuit board 541 so as to overlap a transparent area of the second cover plate 392.

The second circuit board 541 may be combined with charging terminals 521 and 522 of the wireless charging unit 520. For example, the charging terminals 521 and 522 may be placed to overlap each other on the edge area of the first surface of the second circuit board 541, and may be coupled to the charging terminals 521 and 522 through various connecting methods (e.g., laser soldering). The second circuit board 541 may be electrically connected to the wireless charging unit 520 through the charging terminals 521 and 522.

The biometric sensor unit 540 may be at least partially surrounded by the wireless charging unit 520. For example, the biometric sensor unit 540 may be positioned inside the wireless charging unit 520 so as to face the center area of the second rear plate (e.g., the second rear plate 392 of FIG. 3).

The wireless charging unit 520 may wirelessly receive power from an external electronic device (e.g., a wireless charging device). For example, the wireless charging unit 520 may include a planar coil separated from the second circuit board 541 and may generate current by electromagnetic induction generated from the external electronic device. The electronic device may charge a battery (e.g., the battery 370 of FIG. 3) by using the current generated from the wireless charging unit 520.

The planar coil included in the wireless charging unit 520 may be implemented as an antenna. The second circuit board 541 may perform short-range communication with an external device by using the planar coil as an antenna. For example, the second circuit board 541 may wirelessly transmit power required for charging and may transmit a short-range communication signal or a magnetic-based signal including payment data.

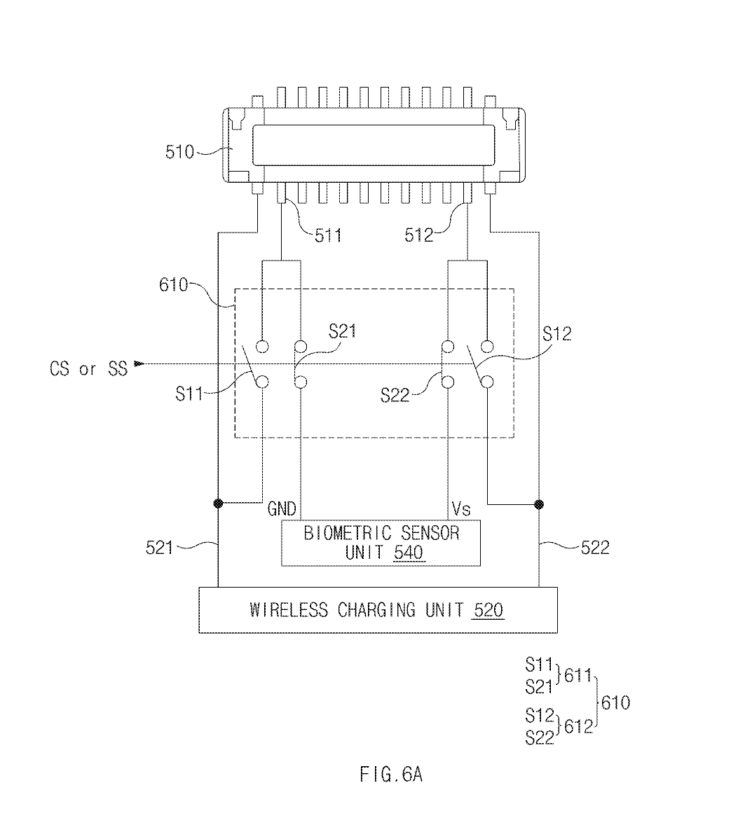

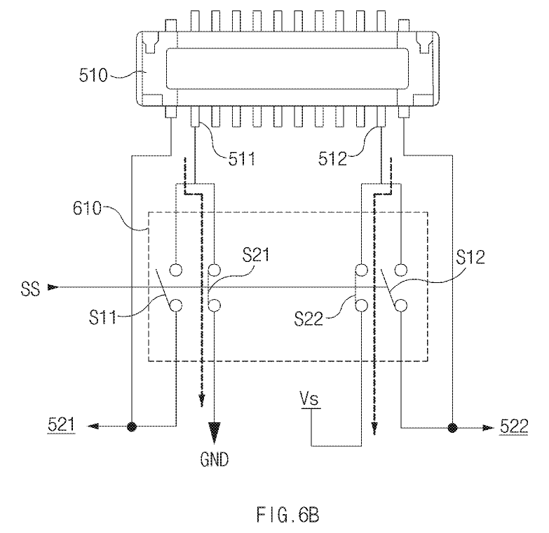

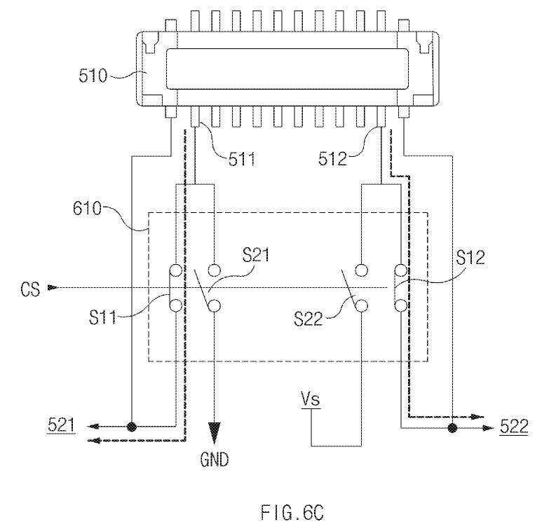

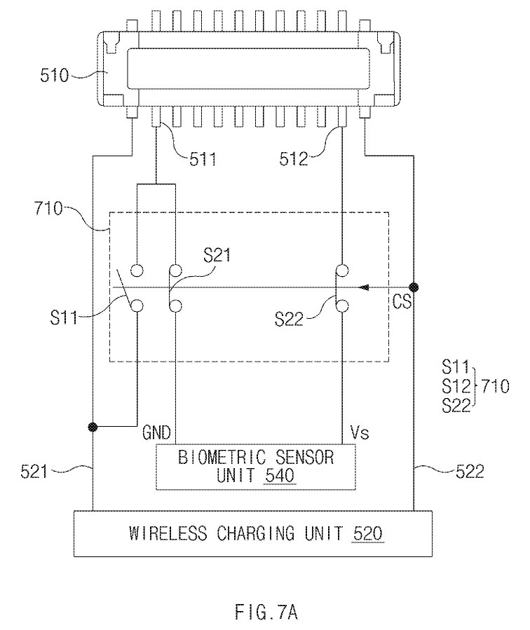

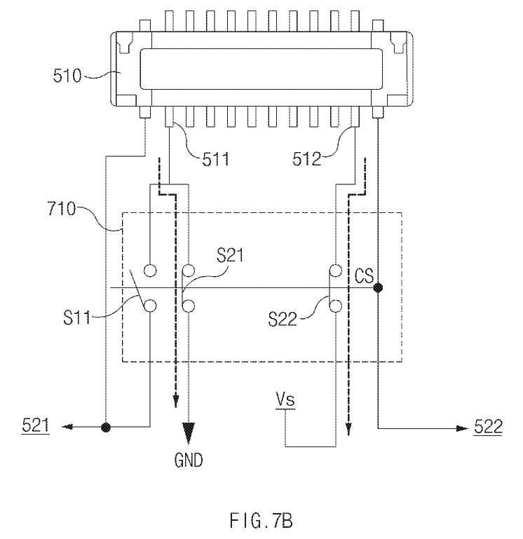

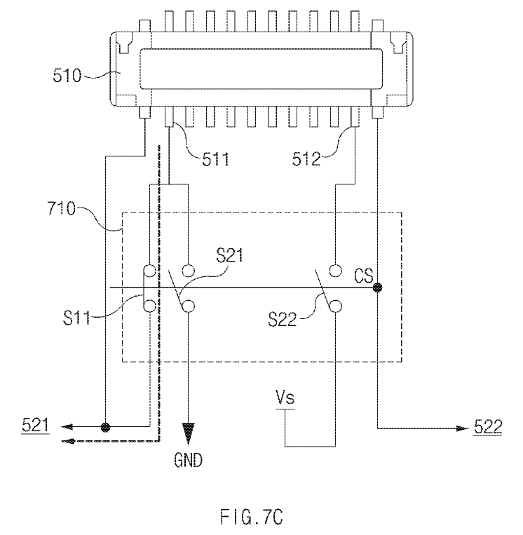

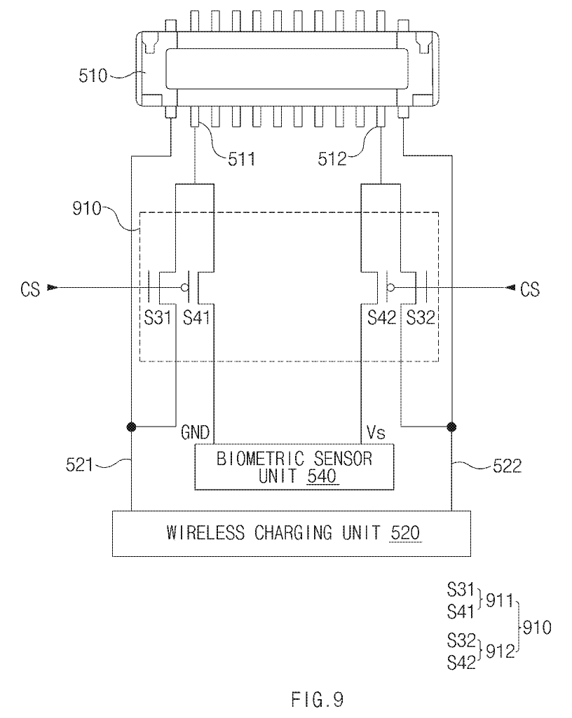

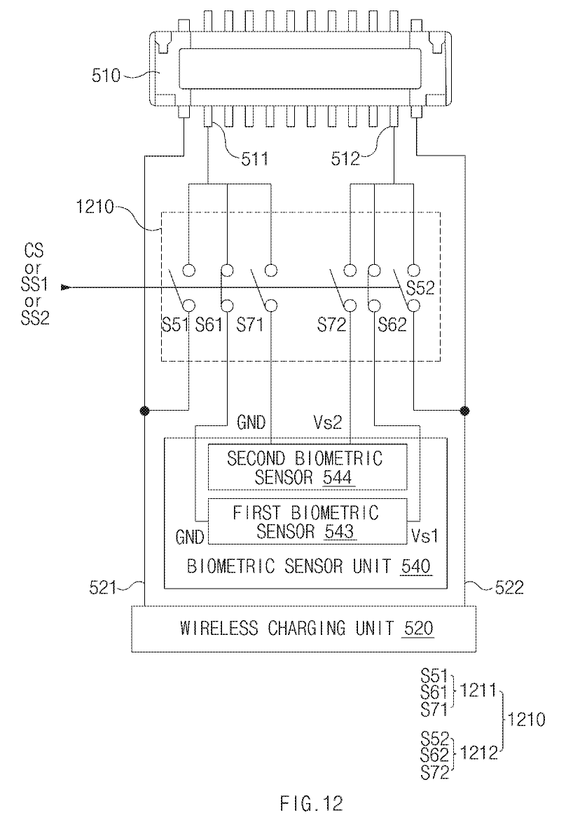

The wireless charging unit 520 may be placed to surround the biometric sensor unit 540. For example, the wireless charging unit 520 may be placed to surround the second circuit board 541 of the biometric sensor unit 540. The wireless charging unit 520 may be formed in a ring shape with an open center such that the biometric sensor unit 540 is capable of being located therein. For example, an opening having a shape corresponding to that of the second circuit board 541 may be formed in the center area of the wireless charging unit 520. The wireless charging unit 520 may extend at least partially toward the biometric sensor unit 540 to be physically and electrically connected to the biometric sensor unit 540. The wireless charging unit 520 may include at least one charging terminal extending toward the biometric sensor unit 540 so as to be electrically connected to the second circuit board 541 of the biometric sensor unit 540. For example, the wireless charging unit 520 may include the first charging terminal 521 and the second charging terminal 522 that are electrically connected to the second circuit board 541 of the biometric sensor unit 540. A switch circuit (e.g., the switch circuit 430 of FIG. 3, the switch circuit 610 of FIG. 6A, the switch circuit 710 of FIG. 7A, the switch circuit 910 of FIG. 9, and the switch circuit 1210 of FIG. 12) may be disposed between the first charging terminal 521 and the second charging terminal 522 and the connector 510. At least part of the switch circuit 710 may be placed so as not to overlap the magnetic body 530.

According to an embodiment, each of the first charging terminal 521 and the second charging terminal 522 may allow information (e.g., packet information) related to wireless charging power control to be transmitted to an external electronic device (e.g., a wireless charging device). For example, the packet information may include at least one of a control error packet (CEP) signal, which includes notification information about the power (or the amount of power) required by the electronic device for charging, and a received power packet (RPP) signal, which includes information about power (or the amount of power) received by the electronic device.

At least one magnetic body 530 may be placed around the wireless charging unit 520. At least one magnetic body 530 may interact with an external magnet provided in an external electronic device (e.g., a wireless charging device). At least one magnetic body 530 may stably place the electronic device on the charging device and may align the wireless charging unit 520 with an antenna provided in the wireless charging device to allow the electronic device to be placed in a location where charging is capable of being performed.

FIG. 6A is a diagram illustrating an electronic device including a plurality of switch elements, according to an embodiment of the disclosure.

FIGS. 6B and 6C are diagrams illustrating an operation of an electronic device including a plurality of switch elements illustrated in FIG. 6A according to various embodiments of the disclosure.

Referring to FIGS. 6A, 6B, and 6C, an electronic device according to an embodiment may include the connector 510, the switch circuit 610, the biometric sensor unit 540, and the wireless charging unit 520.

The switch circuit 610 may include a plurality of switch circuits. The switch circuit 610 may include a first switch circuit 611 and a second switch circuit 612.

The first switch circuit 611 may include a first charging switch element S11 and a first biometric switch element S21. The first charging switch element S11 may be positioned between the first terminal 511 of the connector 510 and the wireless charging unit 520, and may selectively connect the first terminal 511 of the connector 510 and the wireless charging unit 520. The first charging switch element S11 may be turned on in response to a charge detection signal CS from a processor (e.g., the processor 120 of FIG. 1 or the processor 411 of FIG. 4) to electrically connect the first terminal 511 of the connector 510 and the first charging terminal 521 of the wireless charging unit 520. The first charging switch element S11 may be turned off in response to a wearing detection signal SS. The first biometric switch element S21 may be placed between the first terminal 511 of the connector 510 and the biometric sensor unit 540 to selectively connect the first terminal 511 of the connector 510 and the biometric sensor unit 540. The first biometric switch element S21 may be turned on in response to the wearing detection signal SS from a processor (e.g., the processor 120 of FIG. 1 or the processor 411 of FIG. 4) to electrically connect the first terminal 511 of the connector 510 to a ground terminal GND of the biometric sensor unit 540. The first biometric switch element S21 may be turned off in response to the charge detection signal CS.

The second switch circuit 612 may include a second charging switch element S12 and a second biometric switch element S22. The second charging switch element S12 may be positioned between the second terminal 512 of the connector 510 and the wireless charging unit 520 to selectively connect the second terminal 512 of the connector 510 to the wireless charging unit 520. The second charging switch element S12 may be turned on in response to the charge detection signal CS from the processor to electrically connect the second terminal 512 of the connector 510 and the second charging terminal 522 of the wireless charging unit 520. The second charging switch element S12 may be turned off in response to the wearing detection signal SS. The second biometric switch element S22 may be placed between the second terminal 512 of the connector 510 and the biometric sensor unit 540 to selectively connect the second terminal 512 of the connector 510 and the biometric sensor unit 540. The second biometric switch element S22 may be turned on in response to the wearing detection signal SS from the processor to electrically connect the second terminal 512 of the connector 510 and a power terminal Vs of the biometric sensor unit 540. The second biometric switch element S22 may be turned off in response to the charge detection signal CS.

According to an embodiment, the first charging switch element S11, the second charging switch element S12, the first biometric switch element S21, and the second biometric switch element S22 may be the same type of transistor as each other. For example, the first charging switch element S11, the second charging switch element S12, the first biometric switch element S21, and the second biometric switch element S22 may be N-channel metal-oxide-semiconductor (NMOS) transistors or P-channel metal-oxide-semiconductor (PMOS) transistors. The first charging switch element S11 and the second charging switch element S12 may be transistors having the same threshold voltage as each other. The first biometric switch element S21 and the second biometric switch element S22 may be transistors having the same threshold voltage as each other. The first charging switch element S11 may be a transistor having a different threshold voltage from that of the first biometric switch element S21. The second charging switch element S12 may be a transistor having a different threshold voltage from that of the second biometric switch element S22.

The connector 510 may be selectively connected to the biometric sensor unit 540 and the wireless charging unit 520 via the switch circuit 610. The biometric sensor unit 540 may be electrically connected to a first circuit board (e.g., the first circuit board 380 of FIG. 3) via the connector 510 and the switch circuit 610. The wireless charging unit 520 may be electrically connected to the first circuit board (e.g., the first circuit board 380 of FIG. 3) via the connector 510 and the switch circuit 610.

The connector 510 may include a plurality of terminals. The first terminal 511 and the second terminal 512 of the connector 510 may be used as biometric sensing wirings electrically connected to the biometric sensor unit 540 when the electronic device is in a biometric sensing mode. The first terminal 511 and the second terminal 512 of the connector 510 may be used as wireless charging wirings electrically connected to the wireless charging unit 520 when the electronic device is in a wireless charging mode.

The wireless charging unit 520 and the biometric sensor unit 540 may share the first terminal 511 and the second terminal 512 of the connector 510 with each other via the switch circuit 610. The first terminal 511 of the connector 510 may be commonly connected to the first biometric switch element S21 and the first charging switch element S11 to be electrically connected to the first biometric switch element S21 and the first charging switch element S11. The first terminal 511 may transmit an electrical signal related to wireless charging to the wireless charging unit 520 when the first charging switch element S11 is turned on. The first terminal 511 may transmit an electrical signal (e.g., a ground signal GND) related to a biometric signal to the biometric sensor unit 540 when the first biometric switch element S21 is turned on. The second terminal 512 of the connector 510 may be commonly connected to the second biometric switch element S22 and the second charging switch element S12 to be electrically connected to the second biometric switch element S22 and the second charging switch element S12. The second terminal 512 may transmit an electrical signal related to wireless charging to the wireless charging unit 520 when the second charging switch element S12 is turned on. The second terminal 512 may transmit an electrical signal (e.g., a power signal (Vs)) related to a biometric signal to the biometric sensor unit 540 when the second biometric switch element S22 is turned on. Each of the first terminal 511 and the second terminal 512 may be used as a wiring for transmitting and receiving electrical signals related to wireless charging in the wireless charging mode, and for transmitting and receiving electrical signals related to biometric signals in the biometric sensing mode.

When it is determined that the electronic device is being worn (or attached to the body), the biometric sensor unit 540 may operate in the biometric sensing mode by being electrically connected to the first circuit board via the connector 510 and the switch circuit 610. The ground terminal GND of the biometric sensor unit 540 may be electrically connected to the first terminal 511 of the connector 510 via the first switch circuit 611. The power terminal Vs of the biometric sensor unit 540 may be electrically connected to the second terminal 512 of the connector 510 via the second switch circuit 612. The biometric sensor unit 540 may generate body information or health information of a user based on at least one biometric signal received through a first switch circuit 611 and a second switch circuit 612.

When it is determined that the electronic device is connected to an external electronic device (e.g., a wireless charging device), the electronic device may operate in a charging mode as the wireless charging unit 520 is electrically connected to the first circuit board through the connector 510 and the switch circuit 610. The first charging terminal 521 of the wireless charging unit 520 may be electrically connected to the first terminal 511 of the connector 510 through the first switch circuit 611. The second charging terminal 522 of the wireless charging unit 520 may be electrically connected to the second terminal 512 of the connector 510 through the second switch circuit 612. The wireless charging unit 520 may charge a battery included in an electronic device by using power from an external electronic device supplied through the first charging terminal 521 and the second charging terminal 522.

The operation of the electronic device including the first charging switch element S11, the second charging switch element S12, the first biometric switch element S21, the second biometric switch element S22, and the connector 510 will be described with reference to FIGS. 6B and 6C. For example, the connector 510 may be electrically connected to a processor and a power supply unit placed on the first circuit board (e.g., the printed circuit board 380 of FIG. 3).

Referring to FIG. 6B, the wearing detection signal SS from the processor may be applied to the control terminal of each of the first charging switch element S11, the second charging switch element S12, the first biometric switch element S21, and the second biometric switch element S22. In response to the wearing detection signal SS, the first biometric switch element S21 and the second biometric switch element S22 may be turned on together (or simultaneously), and the first charging switch element S11 and the second charging switch element S12 may be turned off together (or simultaneously). The first terminal 511 of the connector 510 may be electrically connected to the ground terminal GND of the biometric sensor unit (e.g., the biometric sensor unit 540 of FIG. 6A) through the turned-on first biometric switch element S21. The second terminal 512 of the connector 510 may be electrically connected to the power terminal Vs of the biometric sensor unit (e.g., the biometric sensor unit 540 of FIG. 6A) through the turned-on second biometric switch element S22.

Referring to FIG. 6C, the charge detection signal CS from the processor may be applied to the control terminal of each of the first charging switch element S11, the second charging switch element S12, the first biometric switch element S21, and the second biometric switch element S22. In response to the charge detection signal CS, the first charging switch element S11 and the second charging switch element S12 may be turned on together (or simultaneously), and the first biometric switch element S21 and the second biometric switch element S22 may be turned off together (or simultaneously). Through the turned-on first charging switch element S11, the first terminal 511 of the connector 510 may be electrically connected to the first charging terminal 521 of a wireless charging unit (e.g., the wireless charging unit 520 of FIG. 6A). The second terminal 512 of the connector 510 may be electrically connected to the second charging terminal 522 of the wireless charging unit through the turned-on second charging switch element S12.

FIG. 7A is a diagram illustrating an electronic device including a plurality of switch elements, according to an embodiment of the disclosure. FIGS. 7B and 7C are diagrams illustrating an operation of an electronic device including a plurality of switch elements illustrated in FIG. 7A according to various embodiments of the disclosure.

Referring to FIGS. 7A, 7B, and 7C, an electronic device according to an embodiment may include the connector 510, the switch circuit 710, the biometric sensor unit 540, and the wireless charging unit 520. Compared to the switch circuit 610 illustrated in FIGS. 6A, 6B, and 6C, the switch circuit 710 may omit either the first charging switch element S11 or the second charging switch element S12. For example, the structure of the switch circuit 710, in which the second charging switch element S12 illustrated in FIGS. 6A, 6B, and 6C is omitted, will be described as an example.

The wireless charging unit 520 and/or a communication module (e.g., the communication module 412 of FIG. 4) may detect packet information related to wireless charging power control used during the communication with an external electronic device (e.g., a wireless charging device) and may provide the charge detection signal CS to the switch circuit 710 based on the detected packet information. According to an embodiment, the second charging terminal 522 of the wireless charging unit 520 may be used as a test terminal for detecting packet information related to wireless charging power control. For example, when the packet information related to wireless charging power control is detected through the second charging terminal 522, the wireless charging unit 520 and/or the communication module (e.g., the communication module 412 of FIG. 4) may transmit the charge detection signal CS of first logic (e.g., high logic or logic corresponding to 1) to the switch circuit 710. When the packet information related to wireless charging power control is not detected through the second charging terminal 522, the wireless charging unit 520 and/or the communication module (e.g., the communication module 412 of FIG. 4) may transmit the charge detection signal CS of second logic (e.g., low logic or logic corresponding to 0) to the switch circuit 710. The wireless charging unit 520 and/or the communication module (e.g., the communication module 412 of FIG. 4) may be included in a receiver integrated circuit (RxIC).

The switch circuit 710 may include the first charging switch element S11, the first biometric switch element S21, and the second biometric switch element S22.

The first charging switch element S11 may be positioned between the first terminal 511 of the connector 510 and the wireless charging unit 520, and may selectively connect the first terminal 511 of the connector 510 and the wireless charging unit 520. The first charging switch element S11 may electrically connect the first terminal 511 of the connector 510 and the first charging terminal 521 of the wireless charging unit 520 by being turned on in response to the charge detection signal CS of the first logic from the wireless charging unit 520 or the communication module (e.g., the communication module 412 of FIG. 4).

The first biometric switch element S21 may be placed between the first terminal 511 of the connector 510 and the biometric sensor unit 540 to selectively connect the first terminal 511 of the connector 510 and the biometric sensor unit 540. The first biometric switch element S21 may be turned on in response to the charge detection signal CS of the second logic to electrically connect the first terminal 511 of the connector 510 and the ground terminal GND of the biometric sensor unit 540.

The second biometric switch element S22 may be placed between the second terminal 512 of the connector 510 and the biometric sensor unit 540 to selectively connect the second terminal 512 of the connector 510 and the biometric sensor unit 540. The second biometric switch element S22 may be turned on in response to the charge detection signal CS of the second logic from the processor to electrically connect the second terminal 512 of the connector 510 and the power terminal Vs of the biometric sensor unit 540.

According to an embodiment, the first charging switch element S11, the first biometric switch element S21, and the second biometric switch element S22 may be the same type of transistor as each other. For example, the first charging switch element S11, the first biometric switch element S21, and the second biometric switch element S22 may be NMOS transistors or PMOS transistors. The first biometric switch element S21 and the second biometric switch element S22 may be transistors having the same threshold voltage as each other. The first charging switch element S11 may be a transistor with a different threshold voltage from those of the first biometric switch element S21 and the second biometric switch element S22.

The connector 510 may be selectively connected to the biometric sensor unit 540 and the wireless charging unit 520 via the switch circuit 710. The biometric sensor unit 540 may be electrically connected to a first circuit board (e.g., the first circuit board 380 of FIG. 3) via the connector 510 and the switch circuit 710. The wireless charging unit 520 may be electrically connected to the first circuit board (e.g., the first circuit board 380 of FIG. 3) via the connector 510 and the switch circuit 710.

The connector 510 may include a plurality of terminals. The first terminal 511 and the second terminal 512 of the connector 510 may be used as biometric sensing wirings electrically connected to the biometric sensor unit 540 when the electronic device is in a biometric sensing mode. The first terminal 511 of the connector 510 may be used as wireless charging wirings electrically connected to the wireless charging unit 520 when the electronic device is in a wireless charging mode.

The wireless charging unit 520 and the biometric sensor unit 540 may share the first terminal 511 of the connector 510 with each other via the switch circuit 710. The first terminal 511 of the connector 510 may be commonly connected to the first biometric switch element S21 and the first charging switch element S11 to be electrically connected to the first biometric switch element S21 and the first charging switch element S11. The first terminal 511 may transmit an electrical signal related to wireless charging to the wireless charging unit 520 when the first charging switch element S11 is turned on. The first terminal 511 may transmit an electrical signal (e.g., a ground signal GND) related to a biometric signal to the biometric sensor unit 540 when the first biometric switch element S21 is turned on. The second terminal 512 of the connector 510 may be commonly connected to the second biometric switch element S22 to be electrically connected to the second biometric switch element S22. The second terminal 512 may transmit an electrical signal (e.g., a power signal (Vs)) related to a biometric signal to the biometric sensor unit 540 when the second biometric switch element S22 is turned on. The first terminal 511 may be used as a wiring for transmitting and receiving electrical signals related to wireless charging in the wireless charging mode, and for transmitting and receiving electrical signals related to biometric signals in the biometric sensing mode. The second terminal 512 may be used as a wiring for transmitting and receiving electrical signals related to biometric signals in the biometric sensing mode.

When it is not determined that the electronic device is connected to an external electronic device (e.g., a wireless charging device) (or when the electronic device is determined not to enter or maintain a wireless charging mode), the biometric sensor unit 540 may operate in the biometric sensing mode by being electrically connected to the first circuit board through the connector 510 and the switch circuit 710. The ground terminal GND of the biometric sensor unit 540 may be electrically connected to the first terminal 511 of the connector 510 via the first biometric switch element S21. The power terminal Vs of the biometric sensor unit 540 may be electrically connected to the second terminal 512 of the connector 510 via the second biometric switch element S22. The biometric sensor unit 540 may generate body information or health information of a user based on at least one biometric signal received through the first biometric switch element S21 and the second biometric switch element S22.

When it is determined that the electronic device is connected to an external electronic device (e.g., a wireless charging device) (or, when the electronic device is determined not to enter or maintain a wireless charging mode), the wireless charging unit 520 may be electrically connected to the first circuit board through the connector 510 and the switch circuit 710, and thus the electronic device may operate in the wireless charging mode. The first charging terminal 521 of the wireless charging unit 520 may be electrically connected to the first terminal 511 of the connector 510 through the first charging switch element S11. The second charging terminal 522 of the wireless charging unit 520 may be directly/electrically connected to the connector 510 without a separate switch element. The wireless charging unit 520 may charge a battery included in an electronic device by using power from an external electronic device supplied through the first charging terminal 521 and the second charging terminal 522.

The operation of the electronic device including the first charging switch element S11, the first biometric switch element S21, the second biometric switch element S22, and the connector 510 will be described with reference to FIGS. 7B and 7C. For example, the connector 510 may be electrically connected to a processor and a power supply unit placed on the first circuit board (e.g., the printed circuit board 380 of FIG. 3).

Referring to FIG. 7B, the charge detection signal CS of the second logic from a wireless charging unit (the wireless charging unit 520 of FIG. 7A) or a communication module (e.g., the communication module 412 of FIG. 4) may be applied to the control terminal of each of the first charging switch element S11, the first biometric switch element S21, and the second biometric switch element S22. In response to the charge detection signal CS of the second logic, the first biometric switch element S21 and the second biometric switch element S22 may be turned on together (or simultaneously), and the first charging switch element S11 may be turned off. The first terminal 511 of the connector 510 may be electrically connected to the ground terminal GND of the biometric sensor unit (e.g., the biometric sensor unit 540 of FIG. 6A) through the turned-on first biometric switch element S21. The second terminal 512 of the connector 510 may be electrically connected to the power terminal Vs of the biometric sensor unit (e.g., the biometric sensor unit 540 of FIG. 6A) through the turned-on second biometric switch element S22.

Referring to FIG. 7C, the charge detection signal CS of the first logic may be applied to the control terminal of each of the first charging switch element S11, the first biometric switch element S21, and the second biometric switch element S22. In response to the charge detection signal CS of the first logic, the first charging switch element S11 may be turned on, and the first biometric switch element S21 and the second biometric switch element S22 may be turned off together (or simultaneously). Through the turned-on first charging switch element S11, the first terminal 511 of the connector 510 may be electrically connected to the first charging terminal 521 of a wireless charging unit (e.g., the wireless charging unit 520 of FIG. 6A).

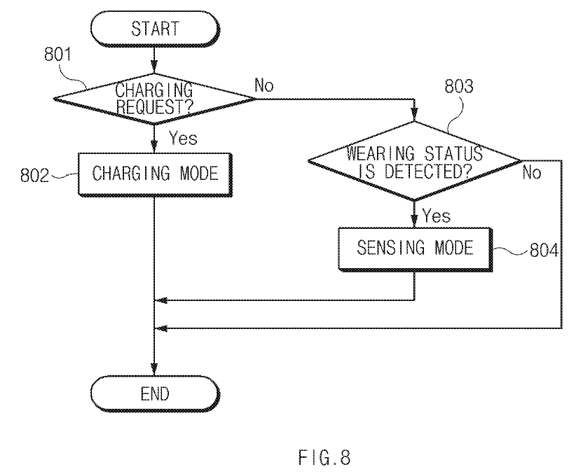

FIG. 8 is a flowchart for describing a method of operating an electronic device including a plurality of switch elements, according to an embodiment of the disclosure. At least some of operations of FIG. 8 may be executed by a processor (e.g., the processor 120 of FIG. 1) of an electronic device. The operating method of the electronic device illustrated in FIGS. 6A to 6C will be described with reference to FIG. 8.

Referring to FIG. 8, in operation 801, the electronic device may determine whether there is a wireless charging request. For example, the electronic device may determine whether the wireless charging request is present, by determining whether a charging voltage is applied to the battery 370 for a specified period of time and/or by determining whether packet information used during wireless charging is detected. Alternatively, the electronic device may determine whether the wireless charging request is present, by determining whether an external electronic device (e.g., a wireless charging device) is contacted. When the wireless charging request of the electronic device is identified (operation 801-Yes), the electronic device may perform operation 802. When the wireless charging request of the electronic device is not identified (operation 801-No), the electronic device may perform operation 803.

When the wireless charging request of the electronic device is identified, in operation 802, the electronic device may allow a first charging switch element and a second charging switch element to electrically connect a connector and the wireless charging unit, and thus the mode of the electronic device may be set to a charging mode. The electronic device may charge a battery by supplying power from an external electronic device to the battery included in the electronic device through a wireless charging unit, the first charging element, the second charging element, and the connector.

When it is determined that the wireless charging request of the electronic device is not identified, in operation 803, the electronic device may determine whether there is a request for obtaining biometric information. For example, the electronic device may determine whether the request for obtaining biometric information is present, based on the detection of the electronic device’s wearing (or body contact) status. When is determined that the electronic device’s wearing status is detected (Yes in operation 803), the electronic device may perform operation 804.

When the request for obtaining biometric information is identified, in operation 804, the electronic device may allow the first biometric switch element and the second biometric switch element to electrically connect the connector and the biometric sensor unit, and thus the mode of the electronic device may be set to a biometric sensing mode. The electronic device may generate body information or health information of a user by using at least one biometric signal obtained from the biometric sensor unit.

FIG. 9 is a diagram illustrating an electronic device including a plurality of switch elements, according to an embodiment of the disclosure.

Referring to FIG. 9, an electronic device according to an embodiment may include the connector 510, the switch circuit 910, the biometric sensor unit 540, and the wireless charging unit 520. At least some of the configurations of the electronic device of FIG. 6A may be applied to at least some of the configurations of the electronic device of FIG. 9. For example, the configurations of the connector 510, the biometric sensor unit 540, and the wireless charging unit 520 of FIG. 6A may be applied to at least some of the configurations of the electronic device of FIG. 9.

The switch circuit 910 may include a plurality of switch circuits. The switch circuit 910 may include a first switch circuit 911 and a second switch circuit 912.

The first switch circuit 911 may include a first charging switch element S31 and a first biometric switch element S41. The first charging switch element S31 may be formed of a different type of transistor from that of the first biometric switch element S41. The first charging switch element S31 may be formed of one of an NMOS transistor and a PMOS transistor, and the first biometric switch element S41 may be formed of the other of the NMOS transistor and the PMOS transistor. For example, the first charging switch element S31 may be formed of an NMOS transistor, and the first biometric switch element S41 may be formed of a PMOS transistor.

The first charging switch element S31 may be positioned between the first terminal 511 of the connector 510 and the wireless charging unit 520, and may selectively connect the first terminal 511 of the connector 510 and the wireless charging unit 520. The first charging switch element S31 may electrically connect the first terminal 511 of the connector 510 and the first charging terminal 521 of the wireless charging unit 520 by being turned on in response to the charge detection signal CS of first logic (e.g., high logic or logic corresponding to 1) from a processor (e.g., the processor 411 of FIG. 4), the wireless charging unit 520, or/and a communication module (e.g., the communication module 412 of FIG. 4).

The first biometric switch element S41 may be placed between the first terminal 511 of the connector 510 and the biometric sensor unit 540 to selectively connect the first terminal 511 of the connector 510 and the biometric sensor unit 540. The first biometric switch element S41 may be turned on in response to the charge detection signal CS of the second logic from the processor, the wireless charging unit 520, or/and the communication module to electrically connect the first terminal 511 of the connector 510 and the ground terminal GND of the biometric sensor unit 540.

The second switch circuit 912 may include a second charging switch element S32 and a second biometric switch element S42. The second charging switch element S32 may be formed of a different type of transistor from that of the second biometric switch element S42. The second charging switch element S32 may be formed of one of an NMOS transistor and a PMOS transistor, and the second biometric switch element S42 may be formed of the other of the NMOS transistor and the PMOS transistor. The second charging switch element S32 may be formed of the same type of transistor as the first charging switch element S31. The second biometric switch element S42 may be formed of the same type of transistor as the first biometric switch element S41. For example, the second charging switch element S32 may be formed of an NMOS transistor, and the second biometric switch element S42 may be formed of a PMOS transistor.

The second charging switch element S32 may be positioned between the second terminal 512 of the connector 510 and the wireless charging unit 520 to selectively connect the second terminal 512 of the connector 510 to the wireless charging unit 520. The second charging switch element S32 may electrically connect the second terminal 512 of the connector 510 and the second charging terminal 522 of the wireless charging unit 520 by being turned on in response to the charge detection signal CS of the first logic from the processor, the wireless charging unit 520, or/and the communication module. The second biometric switch element S42 may be placed between the second terminal 512 of the connector 510 and the biometric sensor unit 540 to selectively connect the second terminal 512 of the connector 510 and the biometric sensor unit 540. The second biometric switch element S42 may be turned on in response to the charge detection signal CS of the second logic from the processor, the wireless charging unit 520, or/and the communication module to electrically connect the second terminal 512 of the connector 510 and the power terminal Vs of the biometric sensor unit 540.

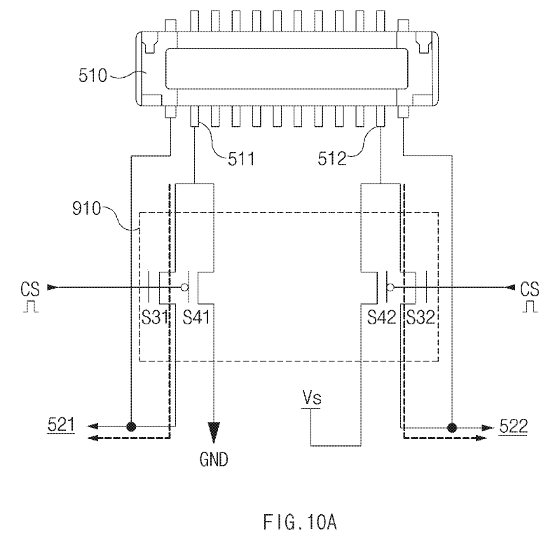

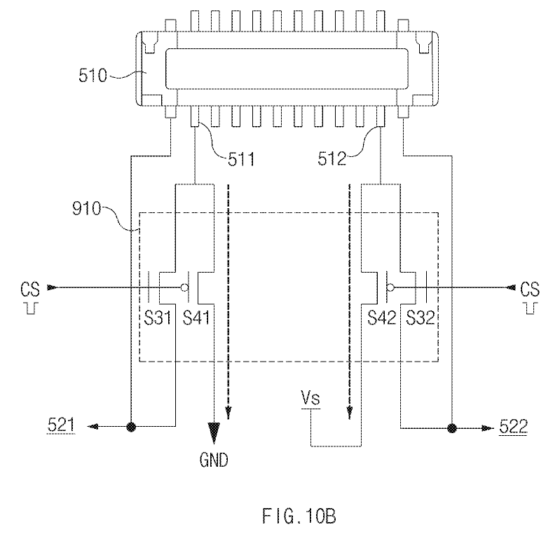

FIGS. 10A and 10B are diagrams for describing an operation of an electronic device including a plurality of switch elements, according to various embodiments of the disclosure.

The connector 510 and the switching circuit 910 illustrated in FIGS. 10A and 10B may be implemented substantially identically to the connector 510 and the switch circuit 910 described in FIG. 9. The operation of the connector 510 and the switching circuit 910 will be primarily described with reference to FIGS. 10A and 10B.

Referring to FIGS. 10A and 10B, an electronic device according to an embodiment may include the first charging switch element S31, the second charging switch element S32, the first biometric switch element S41, the second biometric switch element S42, and the connector 510.

Referring to FIG. 10A, the charge detection signal CS of the first logic may be applied to a control terminal (or a gate terminal) of each of the first charging switch element S31, the second charging switch element S32, the first biometric switch element S41, and the second biometric switch element S42. In response to the charge detection signal CS of the first logic, the first charging switch element S31 and the second charging switch element S32 may be turned on together (or simultaneously), and the first biometric switch element S41 and the second biometric switch element S42 may be turned off together (or simultaneously). Through the turned-on first charging switch element S31, the first terminal 511 of the connector 510 may be electrically connected to the first charging terminal 521 of a wireless charging unit (e.g., the wireless charging unit 520 of FIG. 6A). The second terminal 512 of the connector 510 may be electrically connected to the second charging terminal 522 of the wireless charging unit through the turned-on second charging switch element S32.

Referring to FIG. 10B, the charge detection signal CS of the second logic may be applied to a control terminal (or a gate terminal) of each of the first charging switch element S31, the second charging switch element S32, the first biometric switch element S41 and the second biometric switch element S42. In response to the charge detection signal CS of the second logic, the first biometric switch element S41 and the second biometric switch element S42 may be turned on together (or simultaneously), and the first charging switch element S31 and the second charging switch element S32 may be turned off. The first terminal 511 of the connector 510 may be electrically connected to the ground terminal GND of the biometric sensor unit (e.g., the biometric sensor unit 540 of FIG. 6A) through the turned-on first biometric switch element S41. The second terminal 512 of the connector 510 may be electrically connected to the power terminal Vs of the biometric sensor unit (e.g., the biometric sensor unit 540 of FIG. 6A) through the turned-on second biometric switch element S42.

According to an embodiment, similarly to the electronic device described in FIGS. 7A, 7B, and 7C, the electronic device illustrated in FIGS. 9, 10A, and 10B, may omit either the first charging switch element S31 or the second charging switch element S32. For example, the electronic device illustrated in FIGS. 9, 10A, and 10B, may omit the second charging switch element S32. The connector 510 and the switch circuit 910 illustrated in FIGS. 9, 10A, and 10B, may be implemented substantially identically to the connector 510 and the switch circuit 710 illustrated in FIGS. 7A, 7B, and 7C.

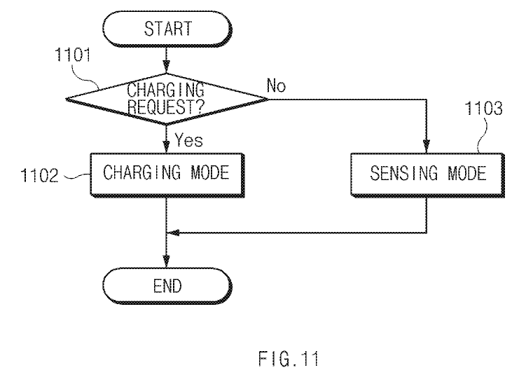

FIG. 11 is a flowchart for describing a method of operating an electronic device including a plurality of switch elements, according to an embodiment of the disclosure. At least some of operations of FIG. 11 may be executed by a processor (e.g., the processor 120 of FIG. 1) of an electronic device.

Referring to FIG. 11, in operation 1101, the electronic device may determine whether there is a wireless charging request. For example, the electronic device may determine whether the wireless charging request is present, by determining whether a charging voltage is applied to the battery 370 for a specified period of time and/or by determining whether packet information used during wireless charging is detected. Alternatively, the electronic device may determine whether the wireless charging request is present, by determining whether an external electronic device (e.g., a wireless charging device) is contacted. When the wireless charging request of the electronic device is identified (operation 1101-Yes), the electronic device may perform operation 1102. When the wireless charging request of the electronic device is not identified (operation 1101-No), the electronic device may perform operation 1103.

When the wireless charging request of the electronic device is identified, in operation 1102, the electronic device may allow a first charging switch element and a second charging switch element to electrically connect a connector and the wireless charging unit, and thus the mode of the electronic device may be set to a charging mode. The electronic device may charge a battery by supplying power from an external electronic device to the battery included in the electronic device through a wireless charging unit, the first charging element, the second charging element, and the connector.

When it is determined that the wireless charging request of the electronic device is not identified, in operation 1103, the electronic device may allow the first biometric switch element and the second biometric switch element to electrically connect the connector and the biometric sensor unit, and thus the mode of the electronic device may be set to a sensing mode. The electronic device may generate body information or health information of a user by using at least one biometric signal obtained from the biometric sensor unit.

FIG. 12 is a diagram illustrating an electronic device including a plurality of switch elements, according to an embodiment of the disclosure.

Referring to FIG. 12, an electronic device according to an embodiment may include the connector 510, the switch circuit 1210, the biometric sensor unit 540, and the wireless charging unit 520. At least some of the configurations of the electronic device of FIG. 6A may be applied to at least some of the configurations of the electronic device of FIG. 12. For example, the configurations of the connector 510 and the wireless charging unit 520 of FIG. 6A may be applied to at least some of the configurations of the electronic device of FIG. 12.

The biometric sensor unit 540 may include a plurality of biometric sensors. The biometric sensor unit 540 may include a first biometric sensor 543 and a second biometric sensor 544. For example, at least one of the first biometric sensor 543 and the second biometric sensor 544 may include at least one of a HRM sensor capable of measuring a heart rate of a user, an ECG sensor capable of measuring an electrocardiogram of the user, a BIA sensor capable of measuring a body fat percentage of the user, and/or a GSR sensor capable of measuring a skin resistance of the user. For example, the first biometric sensor 543 may include the HRM sensor capable of measuring the user’s heart rate, and the second biometric sensor 544 may include the ECG sensor capable of measuring the user’s electrocardiogram. A user’s body information or health information may be generated through at least one biometric signal received through the biometric sensor unit 540 including the first biometric sensor 543 and the second biometric sensor 544. According to an embodiment, the first biometric sensor 543 and the second biometric sensor 544 include independent interfaces and may independently transmit biometric signals to a processor (e.g., the processor 411 of FIG. 4). According to an embodiment, the first biometric sensor 543 and the second biometric sensor 544 include the same interface and may transmit biometric signals to a processor (e.g., the processor 411 of FIG. 4) at different intervals.

The switch circuit 1210 may include a plurality of switch circuits. The switch circuit 910 may include a first switch circuit 1211 and a second switch circuit 1212.

The first switch circuit 1211 may include three or more switch elements. For example, the first switch circuit 1211 may include a first charging switch element S51, a first biometric switch element S61, and a third biometric switch element S71. The first charging switch element S51, the first biometric switch element S61, and the third biometric switch element S71 may be formed of the same type of transistor, or any one of the first charging switch element S51, the first biometric switch element S61, and the third biometric switch element S71 may be formed of a different type of transistor from that of at least one of the remaining switch elements. For example, each of the first charging switch element S51, the first biometric switch element S61, and the third biometric switch element S71 may be formed of either an NMOS transistor or a PMOS transistor. The first charging switch element S51, the first biometric switch element S61, and the third biometric switch element S71 may have different threshold voltages.

The first charging switch element S51 may be positioned between the first terminal 511 of the connector 510 and the wireless charging unit 520, and may selectively connect the first terminal 511 of the connector 510 and the wireless charging unit 520. The first charging switch element S51 may be turned on in response to the charge detection signal CS (or a first control signal) to electrically connect the first terminal 511 of the connector 510 and the first charging terminal 521 of the wireless charging unit 520. When the first charging switch element S51 is turned on, the first biometric switch element S61 and the third biometric switch element S71 may be turned off.

The first biometric switch element S61 is placed between the first terminal 511 of the connector 510 and the first biometric sensor 543, and may selectively connect the first terminal 511 of the connector 510 and the first biometric sensor 543. The first biometric switch element S61 may electrically connect the first terminal 511 of the connector 510 and the ground terminal GND of the first biometric sensor 543 by being turned on in response to a wearing detection signal SS1 (or, a second control signal) of the first logic. When the first biometric switch element S61 is turned on, the first charging switch element S51 and the third biometric switch element S71 may be turned off.

The third biometric switch element S71 is placed between the first terminal 511 of the connector 510 and the second biometric sensor 544, and may selectively connect the first terminal 511 of the connector 510 and the second biometric sensor 544. The third biometric switch element S71 may electrically connect the first terminal 511 of the connector 510 and the ground terminal GND of the second biometric sensor 544 by being turned on in response to a wearing detection signal SS2 (or a third control signal) of the second logic. When the third biometric switch element S71 is turned on, the first charging switch element S51 and the first biometric switch element S61 may be turned off.

The second switch circuit 1212 may include a second charging switch element S52, a second biometric switch element S62, and a fourth biometric switch element S72. The second charging switch element S52, the second biometric switch element S62, and the fourth biometric switch element S72 may be formed of the same type of transistor, or any one of the second charging switch element S52, the second biometric switch element S62, and the fourth biometric switch element S72 may be formed of a different type of transistor from that of at least one of the remaining switch elements. For example, each of the second charging switch element S52, the second biometric switch element S62, and the fourth biometric switch element S72 may be formed of either an NMOS transistor or a PMOS transistor. The second charging switch element S52, the second biometric switch element S62, and the fourth biometric switch element S72 may have different threshold voltages.

The second charging switch element S52 may be positioned between the second terminal 512 of the connector 510 and the wireless charging unit 520 to selectively connect the second terminal 512 of the connector 510 to the wireless charging unit 520. The second charging switch element S52 may be turned on in response to the charge detection signal CS to electrically connect the second terminal 512 of the connector 510 and the second charging terminal 522 of the wireless charging unit 520. When the second charging switch element S52 is turned on, the second biometric switch element S62 and the fourth biometric switch element S72 may be turned off.

The second biometric switch element S62 may be placed between the second terminal 512 of the connector 510 and the biometric sensor unit 540 to selectively connect the second terminal 512 of the connector 510 and the first biometric sensor 543 of the biometric sensor unit 540. The second biometric switch element S62 may electrically connect the second terminal 512 of the connector 510 and a power terminal Vs1 of the first biometric sensor 543 by being turned on in response to the wearing detection signal SS1 (or a second control signal) of the first logic. When the second biometric switch element S62 is turned on, the second charging switch element S52 and the fourth biometric switch element S72 may be turned off.

The fourth biometric switch element S72 is placed between the second terminal 512 of the connector 510 and the second biometric sensor 544, and may selectively connect the second terminal 512 of the connector 510 and the second biometric sensor 544. The fourth biometric switch element S72 may electrically connect the second terminal 512 of the connector 510 and a power terminal Vs2 of the second biometric sensor 544 by being turned on in response to a wearing detection signal SS2 (or a third control signal) of the second logic. When the fourth biometric switch element S72 is turned on, the second charging switch element S52 and the second biometric switch element S62 may be turned off.

In the meantime, the switch circuit described above is not limited to the embodiments described in each drawing, and the switch circuits described in each drawing may be applied in combination with each other. For example, an electronic device according to an embodiment may comprehensively employ the switch circuit 610 described in FIG. 6A, the switch circuit 710 described in FIG. 7A, the switch circuit 910 described in FIG. 9, and the switch circuit 1210 described in FIG. 12. Furthermore, the number and forms of the switch elements included in each of the switch circuit 610 described in FIG. 6A, the switch circuit 710 described in FIG. 7A, the switch circuit 910 described in FIG. 9, and the switch circuit 1210 described in FIG. 12 are not limited to the above-described examples and may be variously changed.

As described above, an electronic device according to at least one embodiment among various embodiments may include the housing 210 including the rear plate 393, the first circuit board 380 disposed inside the housing 210, the biometric sensor unit 540 disposed on the rear plate 393 and including the second circuit board 541, the wireless charging unit 520 disposed on the rear plate 393 and placed to surround at least part of the biometric sensor unit 540, the connector 510 configured to connect the first circuit board and the second circuit board, the switch circuit 610, 710, 910, or 1210 configured to connect either the biometric sensor unit 540 or the wireless charging unit 520 to the connector 510, the processor 411 disposed on the first circuit board 380 and electrically connected to the connector, the biometric sensor unit, and the wireless charging unit.

According to an embodiment, the biometric sensor unit 540 and the wireless charging unit 520 may share at least one terminal 511 among the plurality of terminals of the connector 510 through the switch circuit 610.

According to an embodiment, the switch circuit 610, 710, 910, or 1210 may connect the wireless charging unit 520 and the connector 510 in response to a wireless charging request of the electronic device, and may connect the biometric sensor unit 540 and the connector 510 in response to a wireless charging non-request of the electronic device.

According to an embodiment, the switch circuit 610 or 910 may include the first charging switch element S11 or S31 placed between the first terminal 511 among the plurality of terminals of the connector 510 and the wireless charging unit 520, the second charging switch element S12 or S32 placed between the second terminal 512 of the plurality of terminals of the connector 510 and the wireless charging unit 520, the first biometric switch element S21 or S41 placed between the first terminal 511 of the connector 510 and the biometric sensor unit 540, and the second biometric switch element S22 or S42 placed between the second terminal 512 of the connector 510 and the biometric sensor unit 540.

According to an embodiment, the first charging switch element S31 and the second charging switch element S32 may be formed with one of an NMOS transistor and a PMOS transistor.

According to an embodiment, the first biometric switch element S41 and the second biometric switch element S42 may be formed with the other of the NMOS transistor and the PMOS transistor.

According to an embodiment, the first charging switch element S11, the second charging switch element S12, the first biometric switch element S21, and the second biometric switch element S22 may be formed with either an NMOS transistor or a PMOS transistor.

According to an embodiment, the first charging switch element S11 and the second charging switch element S12 may have different threshold voltages from threshold voltages of the first biometric switch element S21 and the second biometric switch element S22.

According to an embodiment, the processor 411 may be configured to determine whether there is a request for obtaining biometric information, through the biometric sensor unit 540, and to turn on the first biometric switch element S21 and the second biometric switch element S22 when the request for obtaining the biometric information is identified. The processor may be configured to determine whether there is a wireless charging request, through the wireless charging unit 520, and to turn on the first charging switch element S11 and the second charging switch element S12 when the wireless charging request is identified.

According to an embodiment, the processor 411 may be configured to turn on the first biometric switch element S21 and the second biometric switch element S22 when the wireless charging request through the wireless charging unit 520 is not identified.

According to an embodiment, when the wireless charging request is identified, the processor 411 may be configured to electrically connect the first terminal 511 of the connector 510 to the wireless charging unit 520 through the first biometric switch element, which is turned off, and the first charging switch element S11, which is turned on and to electrically connect the second terminal 512 of the connector 510 to the wireless charging unit 520 through the second biometric switch element S22, which is turned off, and the second charging switch element S12, which is turned on.

According to an embodiment, when the wireless charging request is not identified, the processor 411 may be configured to electrically connect the first terminal 511 of the connector 510 to the biometric sensor unit 540 through the first charging switch element S11, which is turned off, and the first biometric switch element S21, which is turned on and to electrically connect the second terminal 512 of the connector 510 to the biometric sensor unit 540 through the second charging switch element S12, which is turned off, and the second biometric switch element S22, which is turned on.

According to an embodiment, when the request for obtaining the biometric information is identified, the processor may be configured to electrically connect the first terminal 511 of the connector 510 to the biometric sensor unit 540 through the first charging switch element, which is turned off, and the first biometric switch element, which is turned on and to electrically connect the second terminal 512 of the connector 510 to the biometric sensor unit 540 through the second charging switch element S12, which is turned off, and the second biometric switch element S22, which is turned on.

According to an embodiment, the processor may be configured to identify the request for obtaining the biometric information based on whether the electronic device is worn and to identify the wireless charging request based on either whether a charging voltage is applied to the battery 370 for a specified period of time or whether packet information used for the wireless charging is detected.

According to an embodiment, the electronic device may further include the plurality of charging terminals 521 and 522 connected to the wireless charging unit 520 and placed on the second circuit board 541.

According to an embodiment, the switch circuit 610, 710, 910, or 1210 may be placed between the connector 510 and the plurality of charging terminals 521 and 522 on the second circuit board 541.

According to an embodiment, the switch circuit 710 may include the first charging switch element S11 placed between the first terminal 511 of the connector 510 and the first charging terminal 521 among the plurality of charging terminals 521 and 522, the first biometric switch element S21 placed between the first terminal 511 of the connector 510 and the biometric sensor unit 540, and the second biometric switch element S22 placed between the second terminal 512 of the connector 510 and the biometric sensor unit 540.

According to an embodiment, a second charging terminal 522 among the plurality of charging terminals may detect packet information used during the wireless charging.

According to an embodiment, the biometric sensor unit 540 may include the first biometric sensor 543 for obtaining first biometric information, and the second biometric sensor 544 for obtaining second biometric information.

According to an embodiment, the switch circuit may include the first charging switch element S51 placed between the first terminal 511 of the connector 510 and the wireless charging unit 520, the second charging switch element S52 placed between the second terminal 512 of the connector 510 and the wireless charging unit 520, the first biometric switch element S61 placed between the first terminal 511 of the connector 510 and the first biometric sensor 543, the second biometric switch element S62 placed between the second terminal 512 of the connector 510 and the first biometric sensor 543, the third biometric switch element S71 placed between the first terminal of the connector 510 and the second biometric sensor 544, and the fourth biometric switch element S72 placed between the second terminal 512 of the connector 510 and the second biometric sensor 544.

According to at least one embodiment among various embodiments, a wearable electronic device may include the first circuit board 380, a rear plate including the first cover plate 391 accommodating the first circuit board and the second cover plate 392 facing the first cover plate 391, the biometric sensor unit 540 disposed between the first cover plate and the second cover plate and including the second circuit board 541, the wireless charging unit 520 disposed between the first cover plate and the second cover plate and placed to surround at least part of the biometric sensor unit, the connector 510 connecting the first circuit board 380 and the second circuit board 541, the switch circuit 610, 710, 910, or 1210 that connects either the biometric sensor unit 540 or the wireless charging unit 520 to the connector 510, and the processor 411 placed on the first circuit board 380 and electrically connected to the connector, the biometric sensor unit, and the wireless charging unit.

According to an embodiment, the processor 411 may allow the switch circuits 610, 710, 910, and 1210 to connect the wireless charging unit 520 and the connector 510 based on a wireless charging request of an electronic device, and may allow the switch circuits 610, 710, 910, and 1210 to connect the biometric sensor unit 540 and the connector 510 in response to a wireless charging non-request of the electronic device.

According to an embodiment, the processor may be configured to identify the request for obtaining the biometric information based on whether the electronic device is worn and to identify the wireless charging request based on either whether a charging voltage is applied to the battery 370 for a specified period of time or whether packet information used for the wireless charging is detected.

According to at least one embodiment among various embodiments, an operating method of a wearable electronic device may include determining whether there is a wireless charging request of the electronic device, based on the wireless charging request of the electronic device, allowing a switch circuit 610, 710, 910, or 1210 disposed between a connector and a wireless charging unit so as to connect the wireless charging unit and the connector 510, which connects a first circuit board disposed on the biometric sensor unit and a second circuit board included in the biometric sensor unit, and based on a wireless charging non-request of the electronic device, allowing the switch circuit 610, 710, 910, or 1210 to connect the biometric sensor unit 540 and the connector 510,

According to at least one embodiment among various embodiments, a non-volatile storage medium may store instructions. When executed by at least one processor in an electronic device, the instructions may cause the at least one processor to perform at least one operation. The at least one operation may include determining whether there is a wireless charging request of the electronic device including the wireless charging unit 520 and the biometric sensor unit 540 disposed on a rear plate, based on the wireless charging request of the electronic device, allowing the switch circuit 610, 710, 910, or 1210 disposed between a connector and a wireless charging unit so as to connect the wireless charging unit and the connector 510, which connects a first circuit board disposed on the biometric sensor unit and a second circuit board included in the biometric sensor unit, and based on a wireless charging non-request of the electronic device, allowing the switch circuit 610, 710, 910, or 1210 to connect the biometric sensor unit 540 and the connector 510.

An embodiment of the disclosure and terms used herein are not intended to limit the technologies described in the disclosure to specific embodiments, and it should be understood that the embodiments and the terms include modification, equivalent, and/or alternative on the corresponding embodiments described herein. With regard to the description of drawings, similar components may be marked by similar reference marks/numerals. Expressions such as “first,” or “second,” and the like, may express their components regardless of their priority or importance and may be used to distinguish one component from another component but is not limited to these components. It will be understood that when an element (e.g., a first element) is referred to as being “(operatively or communicatively) coupled with/to” or “connected to” another element (e.g., a second element), it may be directly coupled with/to or connected to the other element or an intervening element (e.g., a third element) may be present.

According to the situation, the expression “adapted to or configured to” used herein may be interchangeably used as, for example, the expression “suitable for”, “having the capacity to”, “changed to”, “made to”, “capable of” or “designed to”. The expression “a device configured to” may mean that the device is “capable of” operating together with another device or other parts. For example, a “processor configured to (or set to) perform A, B, and C” may mean a dedicated processor (e.g., an embedded processor) for performing corresponding operations or a generic-purpose processor (e.g., a central processing unit (CPU) or an application processor (AP)) which performs corresponding operations by executing one or more software programs which are stored in memory device (e.g., memory).

The term “module” used herein may include a unit, which is implemented with hardware, software, or firmware, and may be interchangeably used with the terms “logic”, “logical block”, “part”, “circuit”, or the like. The “module” may be an integrated component, a minimum unit for performing one or more functions, or a part thereof. The “module” may be implemented mechanically or electronically. For example, the module may include a well-known or to-be-developed application-specific integrated circuit (ASIC) chip, field-programmable gate arrays (FPGAs), or programmable logic device that perform any operations.

According to various embodiments, at least part of a device (e.g., modules or functions thereof) or a method (e.g., operations) may be, for example, implemented by instructions stored in a computer-readable storage medium (e.g., memory) in the form of a program module. The instruction, when executed by a processor (e.g., a processor), may cause the processor to perform a function corresponding to the instruction. The computer-readable recording medium may include a hard disk, a floppy disk, a magnetic media (e.g., a magnetic tape), an optical medium (e.g., compact disc read only memory (CD-ROM) and a digital versatile disc (DVD), a magneto-optical media (e.g., a floptical disk)), embedded memory, or the like. The one or more instructions may contain a code made by a compiler or a code executable by an interpreter.

Each element (e.g., a module or a program module) according to various embodiments may be composed of single entity or a plurality of entities, a part of the above-described sub-elements may be omitted or may further include other elements. Alternatively or additionally, some components (e.g., a module or a program module) may be combined with each other so as to form one entity, so that the functions of the components may be performed in the same manner as before the combination. According to various embodiments, operations executed by modules, program modules, or other components may be executed by a successive method, a parallel method, a repeated method, or a heuristic method. Alternatively, at least some of the operations may be executed in another order or may be omitted, or any other operation may be added.

While the disclosure has been shown and described with reference to various embodiments thereof, it will be understood by those skilled in the art that various changes in form and details may be made therein without departing from the spirit and scope of the disclosure as defined by the appended claims and their equivalents.

1. A wearable electronic device comprising:
a housing including a rear plate;
a first circuit board disposed inside the housing;
a biometric sensor disposed on the rear plate and including a second circuit board;
a wireless charger disposed on the rear plate and placed to surround at least part of the biometric sensor;
a connector configured to connect the first circuit board and the second circuit board and including a plurality of terminals;
a switch circuit configured to connect either the biometric sensor or the wireless charger to the connector;
memory, comprising one or more storage media, storing instructions; and
at least one processor disposed on the first circuit board and electrically connected to the connector, the biometric sensor, and the wireless charger,
wherein the biometric sensor and the wireless charger share at least one terminal among the plurality of terminals of the connector through the switch circuit, and
wherein the switch circuit connects the wireless charger and the connector in response to a wireless charging request of the wearable electronic device, and connects the biometric sensor and the connector in response to a wireless charging non-request of the wearable electronic device.

2. The wearable electronic device of claim 1, wherein the switch circuit includes:
a first charging switch element placed between a first terminal among the plurality of terminals of the connector and the wireless charger;
a second charging switch element placed between a second terminal of the plurality of terminals of the connector and the wireless charger;
a first biometric switch element placed between the first terminal of the connector and the biometric sensor; and
a second biometric switch element placed between the second terminal of the connector and the biometric sensor.

3. The wearable electronic device of claim 2,
wherein the first charging switch element and the second charging switch element are formed with one of an N-channel metal-oxide-semiconductor (NMOS) transistor and a P-channel metal-oxide-semiconductor (PMOS) transistor, and
wherein the first biometric switch element and the second biometric switch element are formed with the other of the NMOS transistor and the PMOS transistor.

4. The wearable electronic device of claim 2,
wherein the first charging switch element, the second charging switch element, the first biometric switch element, and the second biometric switch element are formed with either an NMOS transistor or a PMOS transistor, and
wherein the first charging switch element and the second charging switch element have different threshold voltages from threshold voltages of the first biometric switch element and the second biometric switch element.

5. The wearable electronic device of claim 2,
wherein the instructions, when executed by the at least one processor individually or collectively, further cause the wearable electronic device to:
determine whether there is a request for obtaining biometric information, through the biometric sensor, and
turn on the first biometric switch element and the second biometric switch element when the request for obtaining the biometric information is identified, and
wherein the instructions, when executed by the at least one processor individually or collectively, further cause the wearable electronic device to:
determine whether there is a wireless charging request, through the wireless charger, and
turn on the first charging switch element and the second charging switch element when the wireless charging request is identified.

6. The wearable electronic device of claim 2, wherein the instructions, when executed by the at least one processor individually or collectively, further cause the wearable electronic device to:
turn on the first biometric switch element and the second biometric switch element when a wireless charging request through the wireless charger is not identified.

7. The wearable electronic device of claim 2, wherein, when the wireless charging request is identified, the instructions, when executed by the at least one processor individually or collectively, further cause the wearable electronic device to:
electrically connect the first terminal of the connector to the wireless charger through the first biometric switch element, which is turned off, and the first charging switch element, which is turned on; and
electrically connect the second terminal of the connector to the wireless charger through the second biometric switch element, which is turned off, and the second charging switch element, which is turned on.

8. The wearable electronic device of claim 2, wherein when the wireless charging request is not identified, the processor is configured to:
electrically connect the first terminal of the connector to the biometric sensor through the first charging switch element, which is turned off, and the first biometric switch element, which is turned on; and
electrically connect the second terminal of the connector to the biometric sensor through the second charging switch element, which is turned off, and the second biometric switch element, which is turned on.

9. The wearable electronic device of claim 5, wherein when the request for obtaining the biometric information is identified, the processor is configured to:
electrically connect the first terminal of the connector to the biometric sensor through the first charging switch element, which is turned off, and the first biometric switch element, which is turned on; and
electrically connect the second terminal of the connector to the biometric sensor through the second charging switch element, which is turned off, and the second biometric switch element, which is turned on.

10. The wearable electronic device of claim 2, wherein the instructions, when executed by the at least one processor individually or collectively, further cause the wearable electronic device to:
identify the request for obtaining biometric information based on whether the wearable electronic device is worn; and
identify the wireless charging request based on either whether a charging voltage is applied to a battery for a specified period of time or whether packet information used for the wireless charging is detected.

11. The wearable electronic device of claim 1, further comprising:
a plurality of charging terminals connected to the wireless charger and placed on the second circuit board,
wherein the switch circuit is placed between the connector and the plurality of charging terminals on the second circuit board.

12. The wearable electronic device of claim 11, wherein the switch circuit includes:
a first charging switch element placed between a first terminal of the connector and a first charging terminal among the plurality of charging terminals;
a first biometric switch element placed between the first terminal of the connector and the biometric sensor; and
a second biometric switch element placed between a second terminal of the connector and the biometric sensor.

13. The wearable electronic device of claim 12, wherein a second charging terminal among the plurality of charging terminals detects packet information used during the wireless charging.

14. The wearable electronic device of claim 12, wherein the biometric sensor includes:
a first biometric sensor for obtaining first biometric information; and
a second biometric sensor for obtaining second biometric information.

15. The wearable electronic device of claim 14, wherein the switch circuit includes:
a first charging switch element placed between the first terminal of the connector and the wireless charger;
a second charging switch element placed between the second terminal of the connector and the wireless charger;
a first biometric switch element placed between the first terminal of the connector and the first biometric sensor;
a second biometric switch element placed between the second terminal of the connector and the first biometric sensor;
a third biometric switch element placed between the first terminal of the connector and the second biometric sensor; and
a fourth biometric switch element placed between the second terminal of the connector and the second biometric sensor.

16. A method performed by a wearable electronic device including a wireless charger and a biometric sensor disposed on a rear plate, the method comprising:
determining, by the wearable electronic device, whether there is a wireless charging request of the wearable electronic device;
based on the wireless charging request of the wearable electronic device, allowing, by the wearable electronic device, a switch circuit disposed between a connector and a wireless charger so as to connect the wireless charger and the connector, which connects a first circuit board disposed on the biometric sensor and a second circuit board included in the biometric sensor; and
based on a wireless charging non-request of the wearable electronic device, allowing, by the wearable electronic device, the switch circuit to connect the biometric sensor and the connector,
wherein the biometric sensor and the wireless charger share at least one terminal among a plurality of terminals of the connector through the switch circuit.

17. The method of claim 16,
wherein the allowing of the switch circuit based on the wireless charging request of the wearable electronic device includes:
allowing a first charging switch element placed between a first terminal of the connector and the wireless charger to be turned on, and
allowing a second charging switch element placed between a second terminal of the connector and the wireless charger to be turned on, and
wherein the allowing of the switch circuit based on the wireless charging request of the wearable electronic device includes:
allowing a first biometric switch element placed between the first terminal of the connector and the biometric sensor to be turned off, and
allowing a second biometric switch element placed between the second terminal of the connector and the biometric sensor to be turned off.

18. The method of claim 17, wherein the allowing of the switch circuit based on the wireless charging request of the wearable electronic device includes:
an operation configured to electrically connect the first terminal of the connector to the wireless charger through the first biometric switch element, which is turned off, and the first charging switch element, which is turned on; and
an operation configured to electrically connect the second terminal of the connector to the wireless charger through the second biometric switch element, which is turned off, and the second charging switch element, which is turned on.

19. The method of claim 17,
wherein the allowing of the switch circuit based on the wireless charging non-request of the wearable electronic device includes:
an operation configured to electrically connect the first terminal of the connector to the biometric sensor through the first charging switch element, which is turned off, and the first biometric switch element, which is turned on, and to electrically connect the second terminal of the connector to the biometric sensor through the second charging switch element, which is turned off, and the second biometric switch element, which is turned on, and
wherein the determining of whether there is the wireless charging request of the wearable electronic device includes:
identifying the wireless charging request based on at least one of whether a charging voltage is applied to a battery for a specified period of time or whether packet information used for wireless charging is detected.

20. A non-transitory storage media storing one or more computer programs including computer-executable instructions, when executed by at least one processor in a wearable electronic device, cause the at least one processor to perform at least one operation, the at least one operation including:
determining, by the wearable electronic device, whether there is a wireless charging request of the wearable electronic device including a wireless charger and a biometric sensor disposed on a rear plate;
based on the wireless charging request of the wearable electronic device, allowing, by the wearable electronic device, a switch circuit disposed between a connector and a wireless charger so as to connect the wireless charger and the connector, which connects a first circuit board disposed on the biometric sensor and a second circuit board included in the biometric sensor; and
based on a wireless charging non-request of the wearable electronic device, allowing, by the wearable electronic device, the switch circuit to connect the biometric sensor and the connector,
wherein the biometric sensor and the wireless charger share at least one terminal among a plurality of terminals of the connector through the switch circuit.
